(19) United States
(12) Patent Application Publication
(10) Pub. No.: US 2019/0334037 A1
(43) Pub. Date: Oct. 31, 2019

(54) COATING COMPOSITION, ANTIREFLECTION FILM, MANUFACTURING METHOD THEREFOR, LAMINATE, AND SOLAR CELL MODULE

(71) Applicant: FUJIFILM CORPORATION, Tokyo (JP)

(72) Inventors: Ayana FUJIMAKI, Shizuoka (JP); Hideaki TSUBAKI, Shizuoka (JP); Hirotaka KITAGAWA, Shizuoka (JP); Yu ISOBE, Shizuoka (JP)

(21) Appl. No.: 16/507,036

(22) Filed: Jul. 10, 2019

Related U.S. Application Data
(63) Continuation of application No. PCT/JP2018/003481, filed on Feb. 1, 2018.

(30) Foreign Application Priority Data
Feb. 6, 2017 (JP) 2017-019965
May 10, 2017 (JP) 2017-094246
Dec. 20, 2017 (JP) 2017-244484

(51) Int. Cl. H01L 31/0216; C09D 5/00; C09D 183/04; C09D 7/40; C09D 7/20; C03C 17/30; C03C 17/00; G02B 1/111

(52) U.S. Cl. CPC H01L 31/02168; C09D 5/006; C09D 183/04; C09D 7/67; C09D 7/68; C03C 2218/11; C03C 17/30; C03C 17/007; G02B 1/111; C03C 2217/73; C09D 7/20

(57) ABSTRACT

Provided are a coating composition including polymer particles having a number-average primary particle diameter of 30 nm to 200 nm, a siloxane resin which has a weight-average molecular weight of 600 to 6,000, is a siloxane resin including at least one unit selected from units (1), (2), and (3) described below, and has a total mass of the units (1), (2), and (3) being 95% by mass or more of a total mass of the siloxane resin, and a solvent and applications thereof. R¹'s each independently represent an alkyl group having 1 to 8 carbon atoms or an alkyl fluoride group having 1 to 8 carbon atoms, R²'s each independently represent a hydrogen atom or an alkyl group having 1 to 8 carbon atoms, and, in a case where both the units (1) and (2) are included, the alkyl groups having 1 to 8 carbon atoms represented by R¹'s or R²'s may be identical to or different from each other.

Unit (1): R¹—Si(OR²)₂O_{1/2} unit

Unit (2): R¹—Si(OR²)O_{2/2} unit

Unit (3): R¹—Si—O_{3/2} unit

### CROSS-REFERENCE TO RELATED APPLICATIONS

This application is a continuation application of International Application No. PCT/JP2018/003481, filed Feb. 1, 2018, the disclosure of which is incorporated herein by reference in its entirety. Further, this application claims priority from Japanese Patent Application No. 2017-019965, filed Feb. 6, 2017, Japanese Patent Application No. 2017-094246, filed May 10, 2017, and Japanese Patent Application No. 2017-244484 filed Dec. 20, 2017, the disclosures of which are incorporated herein by reference in their entireties.

### BACKGROUND OF THE INVENTION

### 1. Field of the Invention

The present disclosure relates to a coating composition, an antireflection film, a manufacturing method therefor, a laminate, and a solar cell module.

### 2. Description of the Related Art

In recent years, coating compositions that are intended to be applied to form thin layers that are several micrometers to several tens of nanometers in thickness using a variety of coating methods have been being broadly used in the uses of optical films, printing, and photolithography. For example, in aqueous coating fluids, a solvent containing water as a main component is used, and thus formed films have a low surface energy and excellent transparency. In addition, coating fluids containing an organic solvent as a main component also have advantages of a low viscosity, a low surface tension, and the like, and thus both coating fluids are being used in a variety of uses.

As specific uses of these coating fluids, for example, antireflection films, optical lenses, optical filters, flattening films for thin film transistors (TFT) in a variety of displays, dew condensation prevention films, antifouling films, surface protection films, and the like are exemplified. Among these, antireflection films can be applied to protective films in, for example, solar cell modules, surveillance cameras, lighting equipment, indicators, and the like and are thus useful.

For example, in solar cell modules, the reflection characteristics of glass disposed on an outermost layer on which the sunlight is incident (so-called front glass) have a significant influence on the power generation efficiency, and thus a variety of antireflection coating fluids for glass have been proposed from the viewpoint of improving the power generation efficiency.

As techniques applicable to antireflection films in solar cell modules, for example, a variety of techniques regarding silica-based porous films are proposed.

JP2016-001199A describes that a silica-based porous film having a plurality of holes in a matrix containing silica as a main component, in which a refractive index is in a range of 1.10 to 1.38, holes having a diameter of 20 nm or more are included as the holes, and the number of holes that are opened on an outermost surface and have a diameter of 20 nm or more is 13 holes/10⁶ nm² or less, is capable of maintaining a porous structure for a long period of time and has an excellent antireflection property and an excellent durability even in the case of being directly formed on a glass plate.

In addition, as a technique capable of forming silica-based porous films, for example, JP4512250B discloses that, as a porous dielectric substance having a low dielectric constant that is useful in electronic component industries and a manufacturing method therefor, a removable polymer porogen is dispersed in a dielectric substance such as a siloxane that is substantially compatible with the porogen, the dielectric substance is cured to form a dielectric matrix substance without substantially decomposing the porogen, and the porogen is at least partially removed without substantially decomposing the dielectric matrix substance, thereby forming a porous dielectric substance.

### SUMMARY OF THE INVENTION

Here, for example, antireflection films that are applied as front glass of solar cell modules are disposed on the outermost surface of a module, and thus there is another demand for improvement in scratch resistance in addition to an antireflection property. Additionally, there is still another demand for an antifouling property enabling the easy removal (for example, peeling, swabbing, or the like) of a resin such as an ethylene-vinyl acetate copolymer (hereinafter, abbreviated as “EVA”) that is used as a sealing material in a step of assembling a solar cell module even in a case where the sealing material is attached to and becomes dirty on the antireflection film on the outermost surface of the front glass. In addition, from the viewpoint of obtaining a strong antireflection property, it is demanded to form a thin film having a small unevenness in film thickness as the antireflection film; however, in front glass for solar cell modules, a protrusion and recess structure of a pearskin finish shape is attached on the surface for the purpose of imparting an antiglare property, and it is difficult to form an antireflection film having a small unevenness in film thickness along protrusions and recesses on the surface.

However, coating compositions from which films that are excellent in terms of all of an antireflection property, scratch resistance, and an antifouling property can be obtained or antireflection films that are excellent in terms of all of an antireflection property, scratch resistance, and an antifouling property have not yet been provided.

The present disclosure has been made in consideration of the above-described circumstances.

An object that an embodiment of the present invention intends to achieve is to provide a coating composition from which films that are excellent in terms of an antireflection property, scratch resistance, and an antifouling property can be obtained.

In addition, an object that another embodiment of the present invention intends to achieve is to provide an antireflection film that is excellent in terms of an antireflection property, scratch resistance, and an antifouling property and a manufacturing method therefor.

Furthermore, an object that still another embodiment of the present invention intends to achieve is to provide a laminate having an antireflection film that is excellent in terms of an antireflection property, scratch resistance, and an antifouling property and a solar cell module comprising the laminate.

As means for achieving the above-described objects, the following aspects are included.

<1> A coating composition comprising: polymer particles having a number-average primary particle diameter of 30 nm to 200 nm; a siloxane resin which has a weight-average molecular weight of 600 to 6,000, is a siloxane resin including at least one unit selected from units (1), (2), and (3) described below, and has a total mass of the units (1), (2), and (3) being 95% by mass or more of a total mass of the siloxane resin; and a solvent.

Unit (1): R¹—Si(OR²)₂O_{1/2} unit

Unit(2): R¹—Si(OR²)O_{2/2} unit

Unit(3): R¹—Si—O_{3/2} unit

In the units (1), (2), and (3), R¹'s each independently represent an alkyl group having 1 to 8 carbon atoms or an alkyl fluoride group having 1 to 8 carbon atoms, R²'s each independently represent a hydrogen atom or an alkyl group having 1 to 8 carbon atoms, and, in a case where both the units (1) and (2) are included, the alkyl groups having 1 to 8 carbon atoms represented by R¹'s or R²'s may be identical to or different from each other.

<2> The coating composition according to <1>, in which a proportion of a mass of the polymer particles in a SiO₂-equivalent mass of the siloxane resin is 0.1 or more and 1 or less.

<3> The coating composition according to <1> or <2>, in which a concentration of solid contents is 1% by mass to 20% by mass.

<4> The coating composition according to any one of <1> to <3>, in which the solvent is made up of water and an organic solvent, and a content of the organic solvent is 50% by mass or more of a total mass of the solvent.

<5> The coating composition according to <4>, in which the organic solvent includes an organic solvent having a high boiling point, and a content of the organic solvent having a high boiling point is 1% by mass or more and 20% by mass or less of the total mass of the solvent.

<6> The coating composition according to any one of <1> to <5>, in which the polymer particles are nonionic polymer particles.

<7> The coating composition according to any one of <1> to <6>, in which a pH of the coating composition is 1 to 4.

<8> The coating composition according to any one of <1> to <7>, in which the coating composition further includes an acid, and a pKa of the acid is 4 or less.

<9> The coating composition according to <8>, in which the acid is an inorganic acid.

<10> An antireflection film which is a cured substance of the coating composition according to any one of <1> to <9>.

<11> The antireflection film according to <10>, in which an average film thickness is 80 nm to 200 nm.

<12> A laminate comprising: a base material; and the antireflection film according to <10> or <11>.

<13> A laminate comprising: a base material; and an antireflection film formed on the base material, in which the antireflection film has holes having a hole diameter of 30 nm to 200 nm in a matrix containing silica as a main component, the number of holes that are opened on an outermost surface of the antireflection film and have a diameter of 20 nm or more is 13 holes/10⁶ nm² or less, an average transmittance (T^{AV}) at a wavelength of 380 to 1,100 nm is 94.0% or more, and a pencil hardness measured using a method described in JIS K-5600-5-4 (1999) is 3H or higher.

<14> The laminate according to <13>, in which an average film thickness of the antireflection film is 80 nm to 200 nm, and a standard deviation σ of film thicknesses is 5 nm or less.

<15> The laminate according to any one of <12> to <14>, in which the base material is a glass base material.

<16> A solar cell module comprising: the laminate according to any one of <12> to <15><17> A method for manufacturing an antireflection film comprising: a step of forming a coating film by applying the coating composition according to any one of <1> to <9> onto a base material; a step of drying the coating film formed by application; and a step of firing the dried coating film.

According to an embodiment of the present invention, a coating composition from which films that are excellent in terms of an antireflection property, scratch resistance, and an antifouling property can be obtained is provided.

In addition, according to another embodiment of the present invention, an antireflection film that is excellent in terms of an antireflection property, scratch resistance, and an antifouling property and a manufacturing method therefor is provided.

Furthermore, according to still another embodiment of the present invention, a laminate having an antireflection film that is excellent in terms of an antireflection property, scratch resistance and an antifouling property, and a solar cell module comprising the laminate are provided.

### DESCRIPTION OF THE PREFERRED EMBODIMENTS

Hereinafter, the present disclosure will be described in detail.

In the present specification, numerical ranges expressed using “to” include numerical values before and after “to” as the lower limit value and the upper limit value respectively. In numerical ranges described stepwise in the present specification, an upper limit value or a lower limit value described in a certain numerical range may be substituted into an upper limit value or a lower limit value of another numerical range described stepwise. In addition, in numerical ranges described in the present disclosure, an upper limit value or a lower limit value described in a certain numerical range may be substituted into a value described in examples.

In addition, in the present specification, an amount of individual components in a composition refers to, in a case where there is a plurality of substances that corresponds to the individual components in the composition, unless particularly otherwise described, a total amount of the plurality of substances that is present in the composition.

In the present specification, “(meth)acrylic” refers to any one of both acrylic and methacrylic, and “(meth)acrylate” refers to any one or both of acrylate and methacrylate.

In the present specification, a combination of two or more preferred aspects is a more preferred aspect.

In the present specification, regarding the expression of a group in a compound represented by a formula, an expression of a group that is not described as substituted or unsubstituted refers to, in a case where the group is capable of further having a substituent, unless particularly otherwise described, not only an unsubstituted group but also a group having a substituent. For example, in a case where there is an expression “R represents an alkyl group, an aryl group, or a heterocyclic group” in a formula, this means that “R represents an unsubstituted alkyl group, a substituted alkyl group, an unsubstituted aryl group, a substituted aryl group, an unsubstituted heterocyclic group, or a substituted heterocyclic group”.

In the present specification, a term “step” refers to not only an independent step but also a step that cannot be clearly differentiated from other steps as long as a predetermined object of the step is achieved.

<Coating Composition>

A coating composition according to an embodiment of the present disclosure includes polymer particles having a number-average primary particle diameter of 30 nm to 200 nm (hereinafter, also referred to as “specific polymer particles”), a siloxane resin (hereinafter, also referred to as “specific units”) which has a weight-average molecular weight of 600 to 6,000, is a siloxane resin including at least one unit selected from units (1), (2), and (3) described below, and has a total mass of the units (1), (2), and (3) (hereinafter, appropriately collectively referred to as “specific units”) being 95% by mass or more of a total mass of the siloxane resin; and a solvent.

Unit (1): R¹—Si(OR²)₂O_{1/2} unit

Unit(2): R¹—Si(OR²)O_{2/2} unit

Unit(3): R¹—Si—O_{3/2} unit

In the units (1), (2), and (3), R¹'s each independently represent an alkyl group having 1 to 8 carbon atoms or an alkyl fluoride group having 1 to 8 carbon atoms, R²'s each independently represent a hydrogen atom or an alkyl group having 1 to 8 carbon atoms, and, in a case where both the units (1) and (2) are included, the alkyl groups having 1 to 8 carbon atoms represented by R¹'s or R²'s may be identical to or different from each other.

In the related art, techniques for forming an antireflection film on a base material using a coating fluid including a composition for forming a silica-based porous film are known, and, for example, as described in JP2016-001199A, there are also techniques that pay attention to an antireflection property and durability.

However, in a case where the antireflection film is applied to, for example, front glass of a solar cell module, as described above, there is a demand not only for the improvement of an antireflection property and scratch resistance, but also for an antifouling property enabling the easy removal (for example, peeling, swabbing, or the like) of a substance such as a sealing material in a step of assembling a module even in a case where the substance is attached to the antireflection film, but coating compositions from which films that satisfy all of an antireflection property, scratch resistance, and an antifouling property can be obtained have not yet been provided.

Meanwhile, the coating composition of the embodiment of the present disclosure includes both the specific polymer particles and the specific siloxane resin and thus becomes a coating composition from which films that satisfy all of an antireflection property, scratch resistance, and an antifouling property can be obtained. That is, the specific siloxane resin in the coating composition of the embodiment of the present disclosure has a weight-average molecular weight in a predetermined range and includes the specific units described above, whereby it is considered that, in the case of forming a coating film using the coating composition of the embodiment of the present disclosure, the siloxane resin is segregated on the surface of the coating film, forms a flat outermost layer, and improves scratch resistance and an antifouling property. Furthermore, the fact that the number-average primary particle diameter of the specific polymer particles is 30 nm to 200 nm enables the formation of holes of a random size in an antireflection film to be obtained from the coating composition according to the embodiment of the present disclosure, and it is possible to suppress the formation of an opening portion on the surface of the film and ensure the flatness of the surface of the film while decreasing the refractive index, and thus it is considered that the inclusion of the specific siloxane resin contributes to the formation of a film that is excellent in an antireflection property, scratch resistance, and an antifouling property together with the above-described effect.

Hereinafter, the respective components that are included in the coating composition will be described in detail.

(Specific Polymer Particles)

The coating composition according to the embodiment of the present disclosure includes polymer particles having a number-average primary particle diameter of 30 nm to 200 nm (that is “specific polymer particles”).

The specific polymer particles are particles that can be removed from the coating film formed using the coating composition and preferably particles that can be removed from the coating film by a thermal treatment.

As the particles that can be removed from the coating film by a thermal treatment, for example, particles that are removed by at least one of decomposition or volatilization during the thermal treatment are exemplified.

In a case where the number-average primary particle diameter of the specific polymer particles is set to a 30 nm or more, it becomes possible to form films that are excellent in terms of an antireflection property. This is considered to be because the collapse of holes, formed in a cooling process after the removal of the specific polymer particles from the coating film by a thermal treatment, due to the contraction of the film is suppressed and a sufficient number of holes can be formed in the film.

In addition, in a case where the number-average primary particle diameter of the specific polymer particles is set to 200 nm or less, films that are excellent in terms of an antireflection property, scratch resistance, and an antifouling property can be obtained. This is considered to be because the formation of an opening portion on the outermost surface of the film during the removal of the specific polymer particles from the coating film by the thermal treatment is effectively suppressed.

From the viewpoint of the formation of stable holes, the number-average primary particle diameter of the specific polymer particles is preferably 40 nm or more, more preferably 60 nm or more, and still more preferably 80 nm or more.

In addition, from the viewpoint of suppressing an opening on the outermost surface of the film, the number-average primary particle diameter of the specific polymer particles is preferably 150 nm or less and more preferably 120 nm or less.

The number-average primary particle diameter of the specific polymer particles is measured using a dynamic light scattering method. Specifically, the number-average primary particle diameter can be obtained by measuring a particle size distribution using Microtrac (Version 10.1.2-211BH) manufactured by Nikkiso Co., Ltd.

The thermal decomposition temperature of the specific polymer particles is preferably 200° C. to 800° C., more preferably 200° C. to 500° C., and still more preferably 200° C. to 300° C.

Here, the thermal decomposition temperature refers to a temperature when the mass decrease rate reaches 50% by mass in thermogravimetric/differential thermal analysis (TG/DTA) measurement.

The glass transition temperature (Tg) of the specific polymer particles is preferably 0° C. or higher and more preferably 30° C.

In a case where Tg is set to 0° C. or higher, the scratch resistance of a film to be obtained further improves. This is considered to be because a change in the shape of the specific polymer particles in the coating film is suppressed, and thus stabilized holes can be formed.

The glass transition temperature is obtained from a DSC curve obtained by differential scanning calorimetry (DSC) and, more specifically, obtained from “extrapolated glass transition onset temperature” described in a method for obtaining glass transition temperatures of JIS K7121-1987 “Testing methods for transition temperatures of plastics”.

A polymer that is included in the specific polymer particles is not particularly limited as long as polymer particles having a desired particle diameter can be obtained. The polymer is preferably a homopolymer or copolymer of a monomer selected from the group consisting of (meth)acrylic acid ester-based monomers, styrene-based monomers, diene-based monomers, imide-based monomers, or amide-based monomers.

In addition, from the viewpoint of the liquid aging stability of the coating composition, the polymer that configures the specific polymer particles preferably does not include any ionic group such as an amino group or a carboxy group.

As the (meth)acrylic acid ester-based monomers, methyl (meth)acrylate, ethyl (meth)acrylate, propyl (meth)acrylate, isopropyl (meth)acrylate, butyl (meth)acrylate, isobutyl (meth)acrylate, pentyl (meth)acrylate, hexyl (meth)acrylate, 2-ethylhexyl (meth)acrylate, octyl (meth)acrylate, lauryl (meth)acrylate, nonyl (meth)acrylate, decyl (meth)acrylate, dodecyl (meth)acrylate, cyclohexyl (meth)acrylate, methoxyethly (meth)acrylate, ethoxymethyl (meth)acrylate, propoxyethyl (meth)acrylate, butoxyethyl (meth)acrylate, ethoxypropyl (meth)acrylate, glycidyl (meth)acrylate, and the like are exemplified.

As the styrene-based monomers, styrene, methylstyrene, dimethylstyrene, trimethylstyrene, ethyl styrene, diethyl styrene, triethylstyrene, propyl styrene, butylstyrene, hexylstyrene, heptylstyrene, octylstyrene, fluorostyrene, chlorostyrene, bromostyrene, acetylstyrene, methoxystyrene, α-methylstyrene, and the like are exemplified.

As the diene-based monomers, butadiene, isoprene, cyclopentadiene, 1,3-pentadiene, dicyclopentadiene, and the like are exemplified.

As the imide-based monomers, maleimide, N-methylmaleimide, N-phenylmaleimide, N-cyclohexylmaleimide, and the like are exemplified.

As the amide-based monomers, acrylamide-based derivatives such as acrylamide, N-isopropylacrylamide, hydroxyethyl acrylamide, and 4-acryloylmorphorine are exemplified.

The specific polymer particles preferably have a crosslinking structure in order for stable dispersion in an organic solvent.

Polymer particles having a crosslinking structure can be obtained by polymerizing an emulsifier described below and a crosslinking reactive monomer. Crosslinking reactive monomers that can be used are not particularly limited, examples thereof include crosslinking reactive monomers having an unsaturated double bond in the molecule and crosslinking reactive monomers having a reactive functional group in the molecule (specifically, an epoxy group, an isocyanate group, an alkoxysilyl group, and the like are exemplified), and the crosslinking reactive monomer is selected from the above-described monomers or combinations thereof.

Among these, the crosslinking reactive monomer is preferably a monomer having a radical polymerizable double bond and more preferably a (meth)acrylic acid ester-based monomer or styrene-based monomer having a plurality of radical polymerizable double bonds in the molecule.

As such crosslinking reactive monomers, for example, polyfunctional (meth)acrylate compounds such as ethylene glycol di(meth)acrylate, diethylene glycol di(meth)acrylate, triethylene glycol di(meth)acrylate, 1,4-butanediol di(meth)acrylate, neopentyl glycol di(meth)acrylate, 1,6-hexanediol di(meth)acrylate, allyl (meth)acrylate, trimethylolpropane tri(meth)acrylate, and pentaerythritol tetra(meth)acrylate; aromatic divinyl compounds such as divinyl benzene and divinyl naphthalene; and the like.

The specific polymer particles are preferably nonionic polymer particles (hereinafter, also referred to as “specific nonionic polymer particles”). In a case where the coating composition includes the specific nonionic polymer particles, the compatibility between the specific siloxane resin and the specific nonionic polymer particles improves. Therefore, in a coating film formed using the coating composition, the agglomeration of the specific nonionic polymer particles is suppressed, and the scratch resistance and the antifouling property can be further improved in association with the specific siloxane resin eccentrically present on the surface of the film.

In the present disclosure, “nonionic polymer particles” refers to polymer particles that are synthesized by emulsification polymerization for which a nonionic emulsifier is used and contain a structure derived from the nonionic emulsifier in the structure.

Here, nonionic polymer particles refer to polymer particles that contain the structure derived from the nonionic emulsifier in the structure and substantially do not contain any structures derived from anionic emulsifiers or any structures derived from cationic emulsifiers. The expression “substantially do not contain any structure” indicates that the proportion of the structure derived from the nonionic emulsifier is 99% by mass or more in the total amount of structures derived from emulsifiers.

The proportion of the structure derived from the nonionic emulsifier can be computed by analyzing the fragments of the polymer particles through pyrolysis gas chromatography-mass spectrometry (GC-MS) and a well-known method.

The specific nonionic polymer particles are preferably self-dispersive particles. Self-dispersive particles refer to particles of a polymer that is insoluble in water and alcohols which can be in a state of being dispersed in a medium including water and an alcohol due to the intrinsic hydrophilic portions of the polymer particles. Meanwhile, the state of being dispersed refers to both states of an emulsified state (emulsion) in which the polymer is dispersed in a medium in a liquid state and a dispersed state (suspension) in which the polymer is dispersed in a medium in a solid state.

In addition, the expression “insoluble” indicates that the amount of the polymer dissolved in a medium (100 parts by mass) at 25° C. is 5.0 parts by mass or less.

Self-dispersive particles are used as the specific nonionic polymer particles, whereby the specific nonionic polymer particles can be more stably dispersed in a medium containing an organic solvent such as an alcohol as a main component.

As the nonionic emulsifier for synthesizing the specific nonionic polymer particles, a variety of nonionic emulsifiers can be preferably used. As the nonionic emulsifier, nonionic emulsifiers having an ethylene oxide chain are preferably exemplified, and nonionic reactive emulsifiers having an ethylene oxide chain, which have a radical polymerizable double bond in the molecule, are more preferably exemplified. Due to the nonionic emulsifier, it is possible to obtain a film having a high pencil hardness. A reason therefor is not clear, but is considered that emulsification stability during polymerization is excellent, whereby the dispersed state of the polymer particles in the film becomes uniform, and the distribution of holes becomes uniform.

As the nonionic emulsifier having an ethylene oxide chain, emulsifiers such as a polyxoyethylene alkyl ether, a polyoxyethylene alkyl allyl ether, a polyoxyethyleneoxy propylene blocked copolymer, a polyethylene glycol aliphatic acid ester, a polyoxyethylene sorbitan aliphatic acid ester, or the like are exemplified.

As the reactive emulsifier, monomers having a hydrophilic group such as polyoxyethylene mono(meth)acrylate, polyoxyethylene alkyl phenol ether (meth)acrylic acid ester, polyoxyethylene monomaleic acid esters, derivatives thereof, 2,3-dihydroxypropyl (meth)acrylate, and 2-hydroxyethyl acrylamide, which have a variety of molecular weights (different numbers of moles of ethylene oxide added), are exemplified, and reactive emulsifiers having an oxyethylene chain are preferred.

As the reactive emulsifier having an oxyethylene chain, any emulsifiers can be used as long as an oxyethylene chain is present and the number of closed chains is one or more; however, among them, preferred are emulsifiers in which the number of closed chains in the oxyethylene chain is 2 or more and 30 or less and particularly preferably 3 or more and 15 or less. As the nonionic emulsifier having an oxyethylene chain, at least one selected from the group of these can be used.

As the nonionic emulsifier, a commercially available product may also be used.

Examples of the commercially available product of the nonionic emulsifier include “NOIGEN” series, “AQUARON” series (all manufactured by DSK Co., Ltd.), “LATEMUL PD-420”, “LATEMUL PD-430”, “LATEMUL PD-450”, and “EMULGEN” series (all manufactured by KAO Corporation).

Among these, reactive emulsifiers having an oxyethylene chain and having a radical polymerizable double bond in the molecule such as “AQUARON” series, “LATEMUL PD-420”, “LATEMUL PD-430”, and “LATEMUL PD-450” are most preferably used.

In addition, in the coating composition according to the embodiment of the present disclosure, ionic polymer particles are preferably not used as the polymer particles, but it is also possible to jointly use ionic polymer particles. In the case of mixing ionic polymer particles, the amount of the ionic polymer particles mixed is generally 30 parts by mass or less, preferably 10 parts by mass or less, and most preferably 3 parts by mass or less with respect to 100 parts by mass of the total amount of the polymer particles.

The proportion of the total mass of the specific polymer particles in the SiO₂-equivalent mass of the specific siloxane resin described below is preferably 0.1 or more and 1 or less, more preferably 0.2 or more and 0.9 or less, and still more preferably 0.3 or more and 0.6 or less from the viewpoint of the antireflection property of a film to be obtained.

The proportion of the total mass of the specific polymer particles in the SiO₂-equivalent mass of the specific siloxane resin refers to a value that is obtained from (the mass of the specific polymer particles)/(the SiO₂-equivalent mass of the specific siloxane resin).

The SiO₂-equivalent mass of the specific siloxane resin can be computed from the molecular weight of a siloxane resin by analyzing the structure of the specific siloxane resin that is the subject.

(Specific siloxane resin)

The coating composition according to the embodiment of the present disclosure contains a siloxane resin (that is, “specific siloxane resin”) which has a weight-average molecular weight of 600 to 6,000, includes at least one unit selected from units (1), (2), and (3) described below, and has a total mass of the units represented by (1), (2), and (3) being 95% by mass or more of the total mass of the siloxane resin.

(1): R¹—Si(OR²)₂O_{1/2} unit

(2): R¹—Si(OR²)O_{2/2} unit

(3): R¹—Si—O_{3/2} unit

In the units (1), (2), and (3), R¹'s each independently represent an alkyl group having 1 to 8 carbon atoms, R²'s each independently represent a hydrogen atom or an alkyl group having 1 to 8 carbon atoms, and, in a case where both the units (1) and (2) are included, the alkyl groups having 1 to 8 carbon atoms represented by R¹'s or R²'s may be identical to or different from each other.

The specific siloxane resin includes at least one unit selected from the units (1), (2), and (3) (that is, the specific unit) in a content of 95% by mass or more of the total mass of the specific siloxane resin and has a weight-average molecular weight of 600 to 6,000. The specific unit is a partial structure derived from a trialkoxysilane.

The specific siloxane resin includes the specific unit, whereby, at the time of forming a coating film using the coating composition according to the embodiment of the present disclosure, a siloxane resin having a hydrophobic portion is segregated on the surface of the coating film, and a flat outermost layer can be obtained. At this time, in a case where the total mass of the specific unit is 95% by mass of the total mass of the specific siloxane resin, the siloxane resin is sufficiently segregated on the surface of the coating film, and, consequently, both the scratch resistance and the antifouling property of the antireflection film improve.

From the viewpoint of further improving the scratch resistance and the antifouling property, the proportion of the specific unit in the specific siloxane resin is preferably 98% by mass or more and more preferably 99% by mass or more.

In a case where the weight-average molecular weight of the specific siloxane resin is set to be in a range of 600 to 6,000, it is possible to satisfy both the scratch resistance and the antifouling property of an antireflection film to be obtained.

On the other hand, in a case where the weight-average molecular weight of the specific siloxane resin is less than 600, the scratch resistance of the antireflection film is insufficient. This is considered to be because the number of siloxane bonds in the antireflection film to be obtained is insufficient.

In addition, in a case where the weight-average molecular weight of the specific siloxane resin is more than 6,000, the scratch resistance and the antifouling property are insufficient. This is considered to be because the mobility of the specific siloxane resin degrades, and thus the amount of the specific siloxane resin segregated on the surface of the film decreases in a process of forming the coating film using the coating composition, and the outermost layer is not sufficiently formed.

From the viewpoint of further improving the scratch resistance and the antifouling property, the weight-average molecular weight of the specific siloxane resin is preferably 1,600 to 6,000 and more preferably 1,600 to 3,000.

In the present specification, the weight-average molecular weight of the specific siloxane resin refers to a value measured by gel permeation chromatography (GPC).

In the measurement by GPC, HLC (registered trademark)-8020GPC (Tosoh Corporation) is used as a measurement instrument, three TSKgel (registered trademark) Super Multipore HZ-H (4.6 mm ID×15 cm, Tosoh Corporation) are used as columns, and dimethylformamide is used as an eluent. In addition, as the measurement conditions, the concentration of a specimen is set to 0.45% by mass, the flow rate is set to 0.35 mL/min, the amount of a sample injected is set to 10 μL, and the measurement temperature is set to 40° C., and a differential refractive index (RI) detector is used.

A calibration curve is produced from “standard specimen TSK standard, polystyrene” of Tosoh Corporation: eight samples of “F-40”, “F-20”, “F-4”, “F-1”, “A-5000”, “A-2500”, “A-1000”, and “n-propylbenzene”.

The specific siloxane resin needs to be a siloxane resin obtained using a trialkoxysilane capable of forming the specific unit, and preferred examples thereof include siloxane resins that are obtained by hydrolyzing and condensing at least one of trialkoxysilanes represented by Formula 1.

R¹—Si(OR²)₃ Formula 1

In Formula 1, R¹ represents an alkyl group having 1 to 8 carbon atoms or an alkyl fluoride group having 1 to 8 carbon atoms, R² represents a hydrogen atom or an alkyl group having 1 to 8 carbon atoms, and, in a case where R¹ and R² represent an alkyl group having 1 to 8 carbon atoms, R¹ and R² may be identical to or different from each other.

As examples of the trialkoxysilane represented by Formula 1, trialkoxysilanes such as methyltrimethoxysilane, methyltriethoxysilane, ethyltrimethoxysilane, ethyltriethoxysilane, n-propyltrimethoxysilane, n-propyltriethoxysilane, isopropyltrimethoxy silane, isopropyltriethoxysilane, n-butyltrimethoxysilane, n-butyltriethoxysilane, n-pentyltrimethoxysilane, n-hexyltrimethoxysilane, n-hexyltriethoxysilane, n-heptyltrimethoxysilane, n-octyltrimethoxysilane, 3,3,3-trifluoropropyl trimethoxysilane, and 3,3,3-trifluoropropyl triethoxysilane are exemplified.

Among the trialkoxysilanes represented by Formula 1, preferred are compounds in which R^{l} and R² are alkyl groups having 1 to 6 carbon atoms, more preferred are compounds in which Rⁱ and R² are alkyl groups having 1 to 3 carbon atoms, and still more preferred are methyltrimethoxysilane or methyltriethoxysilane.

For the specific siloxane resin, only one trialkoxysilane capable of forming the specific unit may be used or two or more trialkoxysilanes may be used.

The specific siloxane resin may be obtained by jointly using an alkoxysilane other than the trialkoxysilane capable of forming the specific unit as necessary. In this case, the content of a unit derived from the other alkoxysilane in the specific siloxane resin is less than 5% by mass of the total mass of the specific siloxane resin.

As the alkoxysilane that can be jointly used with the trialkoxysilane capable of forming the specific unit, trialkoxysilanes other than the trialkoxysilanes capable of forming the specific unit, tetraalkoxysilane, dialkoxysilane, and the like are exemplified.

However, as the trialkoxysilanes other than the trialkoxysilanes capable of forming the specific unit, trialkoxysilanes having a phenyl group are not preferred. This is considered to be because the phenyl group has a strong intermolecular force, and thus the segregation of the siloxane resin on the surface of the film in a process of forming the coating film is inhibited.

Examples that can be used as alkoxysilanes other than trialkoxysilanes, tetraalkoxysilanes, dialkoxysilanes, and the like described below are exemplified.

As the examples of the tetraalkoxysilanes, tetramethoxysilane, tetraethoxysilane, tetra-n-propoxysilane, tetraisopropoxysilane, tetra-n-butoxysilane, and the like are exemplified.

As the examples of the dialkoxysilanes, dimethyldimethoxysilane, dimethyldiethoxysilane, di ethyldimethoxysilane, diethyldiethoxysilane, di-n-propyldimethoxysilane, di-n-propyldiethoxysilane, dii sopropyldimethoxy silane, dii sopropyldiethoxysilane, di-n-butyldimethoxysilane, di-n-butyl diethoxysilane, di-n-pentyldimethoxysilane, di-n-pentyl diethoxysilane, di-n-hexyldimethoxysilane, di-n-hexyldiethoxysilane, di-n-heptyldimethoxysilane, di-n-heptyldiethoxysilane, di-n-octyldimethoxysilane, di-n-octyldiethoxysilane, and the like are exemplified.

The alkoxysilanes other than the trialkoxysilanes capable of forming the specific unit may be used singly or two or more alkoxysilanes may be used.

The specific siloxane resin can be obtained by hydrolyzing and condensing a trialkoxysilane that forms the (specific unit) represented by the units (1), (2), and/or (3), and, as a specific synthesis method, it is possible to refer to, for example, JP2000-159892A and the like.

As the siloxane resin that can be preferably used as the specific siloxane resin, commercially available products may also be used. Examples of the commercially available products include KC-89S (manufactured by Shin-Etsu Chemical Co., Ltd.), KR-515 (manufactured by Shin-Etsu Chemical Co., Ltd.), KR-500 (manufactured by Shin-Etsu Chemical Co., Ltd.), X-40-9225 (manufactured by Shin-Etsu Chemical Co., Ltd.), X-40-9246 (manufactured by Shin-Etsu Chemical Co., Ltd.), X-40-9250 (manufactured by Shin-Etsu Chemical Co., Ltd.), and the like.

The content of the specific siloxane resin is preferably 1% by mass to 20% by mass, more preferably 2% by mass to 10% by mass, and still more preferably 3% by mass to 8% by mass of the total mass of the coating composition.

(Solvent)

The coating composition according to the embodiment of the present disclosure includes a solvent. The solvent is preferably a solvent that disperses the specific polymer particles and is capable of dissolving the specific siloxane resin.

In addition, the solvent may be a solvent made of a single liquid or may be a mixture of two or more liquids.

The content of the solvent is preferably 80% by mass to 99% by mass, more preferably 90% by mass to 98% by mass, and still more preferably 92% by mass to 97% by mass of the total mass of the coating composition.

The solvent preferably includes at least water. From the viewpoint of further improving the scratch resistance of a film to be obtained, the content of water in the coating composition is preferably 5% by mass to 70% by mass, more preferably 5% by mass to 50% by mass, and still more preferably 5% by mass to 30% by mass of the total mass of the coating composition. In a case where the content of water is set to 5% by mass or more, it is considered that the hydrolytic condensation of the siloxane resin is accelerated and the silica matrix can be efficiently obtained. Meanwhile, in the present disclosure, the silica matrix refers to a phase obtained by the condensation of a hydrolysable silane compound or the like.

Water that is used in the coating composition is preferably water including no impurities or having a decreased content of impurities. For example, deionized water is preferably exemplified.

The coating composition preferably contains an organic solvent. The organic solvent is not particularly limited as long as the solvent disperses the specific polymer particles and dissolves the specific siloxane resin.

As examples of the organic solvent, an alcohol-based solvent, an ester-based solvent, a ketone-based solvent, an ether-based solvent, an amide-based solvent, and the like are exemplified.

Examples of the alcohol-based solvent include alcohol-based solvents such as methanol, ethanol, 1-propanol, 2-propanol, 1-butanol, 2-butanol, 2-methyl-1-propanol, tert-butyl alcohol, 1-pentanol, 1-hexanol, cyclopentanol, and cyclohexanol, glycol-based solvents such as ethylene glycol, diethylene glycol, and triethylene glycol, glycol ether-based solvents containing a hydroxyl group such as ethylene glycol monomethyl ether, propylene glycol monomethyl ether, diethylene glycol monomethyl ether, triethylene glycol monoethyl ether, ethylene glycol monoethyl ether, ethylene glycol monopropyl ether, ethylene glycol monobutyl ether, and propylene glycol monoethyl ether, and the like.

Examples of the ester-based solvent include methyl acetate, ethyl acetate, propyl acetate, isopropyl acetate, butyl acetate, isobutyl acetate, pentyl acetate, isopenyl acetate, hexyl acetate, cyclohexyl acetate, propylene glycol monomethyl ether acetate, ethyl lactate, butyl lactate, propyl lactate, γ-butyrolactone, and the like.

Examples of the ketone-based solvent include acetone, methyl ethyl ketone, methyl isobutyl ketone, cyclopentanone, cyclohexanone, and the like.

Examples of the ether-based solvent include tetrahydrofuran, 1,4-dioxane, diisopropyl ether, tert-butyl methyl ether, cyclopentyl methyl ether, diethylene glycol dimethyl ether, propylene glycol dimethyl ether, anisole, and the like.

As the amide-based solvent, for example, N-methyl-2-pyrrolidone, N-ethyl-2-pyrrolidone, N,N-dimethylacetamide, N,N-dimethylformamide, and the like are exemplified.

Among these, from the viewpoint of the dispersibility of the specific polymer particles, the alcohol-based solvents are preferred, monovalent alcohols are more preferably used, ethanol or 2-propanol is still more preferably used, and 2-propanol is particularly preferably used.

As the solvent, both water and an organic solvent are preferably contained, and the solvent is more preferably a solvent made up of water and an organic solvent. As a preferred combination of water and an organic solvent, a combination of water and the above-described organic solvent is preferred, and a combination of water and 2-propanol is particularly preferred.

The proportion of the organic solvent in the total mass of the solvent is preferably 50% by mass or more, more preferably 70% by mass or more, and still more preferably 80% by mass or more. The upper limit of the proportion of the organic solvent is not particularly limited and can be set to, for example, 95% by mass or less.

In a case where the proportion of the organic solvent in the total mass of the solvent is set to 50% by mass or more, it is possible to obtain antireflection films that are superior in terms of the antireflection property. This is considered to be because it is easy to obtain coating films having a small unevenness in film thickness.

As the organic solvent, an organic solvent having a high boiling point is preferably included.

From the viewpoint of further alleviating the unevenness in the film thickness of the antireflection film, the organic solvent preferably includes an organic solvent having a boiling point of 100° C. or lower and an organic solvent having a high boiling point. Here, the organic solvent having a high boiling point refers to an organic solvent having a boiling point that is higher than 100° C.

The upper limit of the boiling point of the organic solvent having a high boiling point is not particularly limited, but is preferably 200° C. or lower, more preferably 170° C. or lower, and particularly preferably 150° C. or lower from the viewpoint of reducing the drying load.

The organic solvent having a high boiling point is not particularly limited as long as the organic solvent having a high boiling point disperses the specific polymer particles and dissolve the specific siloxane resin. As examples of the organic solvent having a high boiling point, alcohol-based solvents, ester-based solvents, ketone-based solvents, ether-based solvents, amide-based solvents, and the like are exemplified.

As the alcohol-based organic solvent having a high boiling point, for example, 1-butanol (boiling point: 118° C.), 1-methoxy-2-propanol (boiling point: 120° C.), 1-propoxy-2-propanol (boiling point: 149° C.), ethylene glycol (boiling point: 197° C.), propylene glycol (boiling point: 188° C.), diethylene glycol (boiling point: 244° C.), triethylene glycol (boiling point: 287° C.), glycerin (boiling point: 290° C.), ethylene glycol monomethyl ether (boiling point: 124° C.), diethylene glycol monomethyl ether (boiling point: 193° C.), diethylene glycol monobutyl ether (boiling point: 230° C.), triethylene glycol monobutyl ether (boiling point: 272° C.), and the like are exemplified.

As the ester-based organic solvent having a high boiling point, for example, butyl acetate (boiling point: 126° C.), pentyl acetate (boiling point: 149° C.), isopentyl acetate (boiling point: 142° C.), y-butyrolactone (boiling point: 204° C.), and the like are exemplified.

As the ketone-based organic solvent having a high boiling point, for example, methyl isobutyl ketone (boiling point: 116° C.), dipropyl ketone (boiling point: 145° C.), cyclohexanone (boiling point: 156° C.), and the like are exemplified.

As the ether-based organic solvent having a high boiling point, for example, 1,4-dioxane (boiling point: 101° C.), cyclopentyl methyl ether (boiling point: 106° C.), and the like are exemplified.

As the amide-based organic solvent having a high boiling point, for example, N-methyl pyrrolidone (boiling point: 204° C.), N-ethyl pyrrolidone (boiling point: 218° C.), and the like are exemplified.

Among these, from the viewpoint of the dispersibility of the specific polymer particles, the solubility of the specific siloxane resin, and the reduction of the drying load, it is possible to preferably use 1-butanol, 1-methoxy-2-propanol, and 1-propoxy-2-propanol as the organic solvent having a high boiling point, and 1-methoxy-2-propanol is most preferred.

The proportion of the organic solvent having a high boiling point in the mass of all of the solvents is preferably 1% by mass to 20% by mass, more preferably 2% by mass to 10% by mass, and particularly preferably 3% by mass to 5% by mass. In a case where the proportion of the solvent having a high boiling point is set to be in the above-described range, it is possible to control the drying rate in a step of forming a coating film and reduce the unevenness in the film thickness of the coating film.

In addition, as front glass or the like that is mounted in solar cell modules, glass base materials provided with a protrusion and recess structure for the purpose of imparting an antiglare property are being broadly used. In a case where the organic solvent having a high boiling point is used in the above-described aspect, the coating composition according to the embodiment of the present disclosure is capable of reducing the unevenness in the film thickness of the coating film even in the case of using a base material having a protrusion and recess structure on the surface such as a glass base material for solar cell modules.

Here, the base material having a protrusion and recess structure refers to a base material having an arithmetic average surface roughness Ra of 0.1 μm to 1.0 μm. Ra of the base material having a protrusion and recess structure is more preferably 0.2 μm to 0.7 μm from the viewpoint of imparting functions such as an antiglare property and the prevention of reflection. The arithmetic average roughness Ra in the present disclosure refers to a value that is measured using a surface roughness meter (product No.: HANDYSURF E-35B, manufactured by Tokyo Seimitsu Co., Ltd.) according to JIS-B0601.

(Acid)

The coating composition according to the embodiment of the present disclosure preferably includes at least one acid. The acid may be any of an organic acid or an inorganic acid.

As the organic acid, for example, formic acid (pKa: 3.8), acetic acid (pKa: 4.8), lactic acid (pKa: 3.7), oxalic acid (pKa: 1.0), malonic acid (pKa: 2.7), succinic acid (pKa: 4.0), maleic acid (pKa: 1.8), fumaric acid (pKa: 2.9), citric acid (pKa: 2.9), tartaric acid (pKa: 2.8), methanesulfonic acid (pKa: −2.6), p-toluenesulfonic acid (pKa: −2.8), camphorsulfonic acid (pKa: 1.2), phenylphosphonic acid (pKa: 1.8), 1-hydroxyethane-1,1-diphosphonic acid (pKa: 1.4), and the like are exemplified. Among these, acetic acid having volatility is preferred.

As the inorganic acid, for example, hydrochloric acid (pKa: −8.0), nitric acid (pKa: −1.3), sulfuric acid (pKa: −3.0), phosphoric acid (pKa: 2.1), boric acid (pKa: 9.2), and the like are exemplified. Among these, from the viewpoint of volatility, hydrochloric acid and nitric acid are preferred, and nitric acid having a poor metal corrosion property is more preferred.

The content of the acid is preferably 0.01% by mass to 1.0% by mass of the total mass of the coating composition. The acid may be used singly or two or more acids may be used in combination. In the case of using two or more acids, any of a combination of different organic acids, a combination of different inorganic acids, or a combination of an organic acid and an inorganic acid may be used.

From the viewpoint of improving the coatability of the coating composition, the coating composition preferably includes an acid having a pKa of 4 or less. pKa of the acid refers to the first dissociation constant of the acid in water at 25° C. pKa of the acid can be confirmed from Chemistry handbooks or the like.

The coating composition may contain both an acid having a pKa of 4 or less and an acid having a pKa of more than 4.

The acid having a pKa of 4 or less may be an organic acid or an inorganic acid, but is preferably an inorganic acid. Examples of the inorganic acid having a pKa of 4 or less include hydrochloric acid (pKa: −8.0), nitric acid (pKa: −1.4), sulfuric acid (pKa: −3.0), and phosphoric acid (pKa: 2.1). Among these, from the viewpoint of volatility, hydrochloric acid and nitric acid are more preferred, and nitric acid having a poor metal corrosion property is particularly preferred.

(Other Components)

The coating composition may include components other than the above-described components.

As the other components, inorganic particles having a number-average primary particle diameter of 3 nm to 100 nm, a surfactant, a thickener, and the like are exemplified.

<Inorganic Particles Having Number-Average Primary Particle Diameter of 3 nm to 100 nm>

The coating composition may contain inorganic particles having a number-average primary particle diameter of 3 nm to 100 nm (hereinafter, also referred to as “specific inorganic particles”). In a case where the coating composition contains inorganic particles having a number-average primary particle diameter of 3 nm to 100 nm, it is possible to improve the scratch resistance and the antifouling property of a film to be obtained while maintaining a favorable antireflection characteristic.

The specific inorganic particles are particles including at least one of boron, phosphorus, silicon, aluminum, titanium, zirconium, zinc, tin, indium, gallium, germanium, antimony, molybdenum, cerium, or the like and preferably particles of an oxide including at least one element of the above-described elements. As such oxide particles, particles of silicon oxide (silica), titanium oxide, aluminum oxide (alumina), zinc oxide, germanium oxide, indium oxide, tin oxide, antimony oxide, cerium oxide, zirconium oxide, and the like are exemplified. As the specific inorganic particles, metal oxides other than those exemplified herein may also be included.

From the viewpoint of further improving the antireflection property and the scratch resistance of the film, as the specific inorganic particles, silica or alumina particles are preferably used, and silica particles are more preferably used. As the silica particles, for example, hollow silica particles porous silica particles, non-porous silica particles, and the like are exemplified. The shape of the silica particle is not particularly limited and may be, for example, any shape of a spherical shape, an elliptical shape, a chain shape, and the like.

In addition, the silica particles may be silica particles having a surface treated with an aluminum compound or the like.

The coating composition may include two or more types of specific inorganic particles. In the case of including two or more types of specific inorganic particles, the coating composition may include two or more types of specific inorganic particles that are different in at least any one of the shape, the particle diameter, or the element composition.

The number-average primary particle diameter of the specific inorganic particles is 3 nm to 100 nm, and, in a case where the particle diameter is set to 3 nm or more, it is possible to obtain a sufficient scratch resistance improvement effect of the addition of the specific inorganic particles. In addition, in a case where the particle diameter is set to 100 nm or less, it is possible to maintain the porosity of the film at an appropriate value in spite of the addition of the specific inorganic particles, and an excellent antireflection property can be obtained.

The number-average primary particle diameter of the specific inorganic particles is preferably 80 nm or less, more preferably 30 nm or less, and particularly preferably 15 nm or less.

The number-average primary particle diameter of the specific inorganic particles can be obtained from an image of a photograph captured by observing the dispersed silica specific inorganic particles using a transmission electron microscope. Specifically, for 200 particles randomly extracted from the image of the photograph, the projected areas of the specific inorganic particles are measured, circle-equivalent diameters are obtained from the measured projected areas, and a value obtained by arithmetically averaging the values of the obtained circle-equivalent diameters is regarded as the number-average primary particle diameter of the specific inorganic particles.

The silica particles that are preferably included in the coating composition are preferably non-porous silica particles.

“Non-porous silica particles” refer to silica particles having no pores in the particles and are differentiated from silica particles having pores in the particles such as hollow silica particles, porous silica particles, and the like. Meanwhile, silica particles having a core-shell structure in which the core such as a polymer or the like is present in the particles and the shell of the core is configured of silica or a precursor of silica (a material that changes to silica by, for example, firing) are not regarded as the “non-porous silica particles”.

In the case of firing the coating film, the state of the non-porous silica particles being present in the coating film are considered to change before and after the firing. Specifically, it is considered that, in the coating film before firing, the respective non-porous silica particles are present as a single particle (here, a state in which particles are gathered together such as a state in which particles are agglomerated by Van der Walls forces is regarded as a single particle), and, in the coating film after firing, at least some of a plurality of non-porous silica particles are present as particle-connected bodies in which the particles are connected to each other.

In a case where the silica particles that are included in the coating composition are non-porous silica particles, the scratch resistance further improves. This is considered to be because, due to the firing of the coating film, a plurality of non-porous silica particles is connected to each other, and particle-connected bodies are formed, and thus the hardness of the film increases.

As the silica particles that are preferably used, commercially available products may also be used. Examples of the commercially available products include NALCO (registered trademark) 8699 (water dispersion of non-porous silica particles, number-average primary particle diameter: 3 nm, solid content: 15% by mass, manufactured by Katayama Nalco Inc.), NALCO (registered trademark) 1130 (water dispersion of non-porous silica particles, number-average primary particle diameter: 8 nm, solid content: 30% by mass, manufactured by Katayama Nalco Inc.), NALCO (registered trademark) 1030 (water dispersion of non-porous silica particles, number-average primary particle diameter: 13 nm, solid content: 30% by mass, manufactured by Katayama Nalco Inc.), NALCO (registered trademark) 1050 (water dispersion of non-porous silica particles, number-average primary particle diameter: 20 nm, solid content: 50% by mass, manufactured by Katayama Nalco Inc.), NALCO (registered trademark) 1060 (water dispersion of non-porous silica particles, number-average primary particle diameter: 60 nm, solid content: 50% by mass, manufactured by Katayama Nalco Inc.), SNOWTEX (registered trademark) ST-OXS (water dispersion of non-porous silica particles, number-average primary particle diameter: 4 nm to 6 nm, solid content: 10% by mass, manufactured by Nissan Chemical Corporation), SNOWTEX (registered trademark) ST-O (water dispersion of non-porous silica particles, number-average primary particle diameter: 10 nm to 15 nm, solid content: 20% by mass, manufactured by Nissan Chemical Corporation), SNOWTEX (registered trademark) ST-O-40 (water dispersion of non-porous silica particles, number-average primary particle diameter: 20 nm to 25 nm, solid content: 40% by mass, manufactured by Nissan Chemical Corporation), SNOWTEX (registered trademark) ST-OYL (water dispersion of non-porous silica particles, number-average primary particle diameter: 50 nm to 80 nm, solid content: 20% by mass, manufactured by Nissan Chemical Corporation), SNOWTEX (registered trademark) ST-OUP (water dispersion of non-porous silica particles, number-average primary particle diameter: 40 nm to 100 nm, solid content: 15% by mass, manufactured by Nissan Chemical Corporation), and the like.

The specific inorganic particles can be added to an extent that the effect of the present invention is not impaired, and regarding the content, the content ratio of the specific inorganic particles to the specific siloxane resin is preferably 0.03 to 1.0, more preferably 0.03 to 0.5, and most preferably 0.03 to 0.1 in terms of the mass ratio. In a case where the content ratio of the inorganic particles to the specific siloxane resin is 0.03 or more, a film having an excellent scratch resistance is likely to be obtained. In a case where the content ratio of the inorganic particles to the specific siloxane resin is 1.0 or less, protrusions and recesses on the surface are small, such a content ratio is advantageous to the formation of a film having a favorable surface status, and an excellent antifouling property is easily obtained.

<Surfactant>

The coating composition may contain a surfactant. In a case where the coating composition contains a surfactant, it is effective to improve the wettability of the coating composition to a base material.

As the surfactant, for example, acetylene-based nonionic surfactants, polyol-based nonionic surfactants, and the like can be exemplified. In addition, as the surfactant, commercially available products on sale may also be used, and it is possible to use, for example, OLFINE series manufactured by Nissin Chemical Co., Ltd. (for example, OLFINE EXP. 4200, OLFINE EXP. 4123, and the like), TRITON BG-10 manufactured by The Dow Chemical Company, MYDOL series manufactured by KAO Corporation (for example, MYDOL 10, MYDOL 12, and the like), and the like.

<Thickener>

The coating composition may contain a thickener. In a case where the coating composition includes a thickener, it is possible to adjust the viscosity of the coating composition.

As the thickener, for example, polyether, urethane-modified polyether, polyacrylic acid, polyacrylic sulfonic acid salts, polyvinyl alcohols, polysaccharides, and the like are exemplified. Among these, polyether, modified polyacrylic sulfonic acid salts, and polyvinyl alcohols are preferred. Commercially available products on sale as thickeners may also be used, and examples of the commercially available products include SN THICKENER 601 (polyether) and SN THICKENER 615 (modified polyacrylic sulfonic acid salt) manufactured by San Nopco Limited, polyvinyl alcohols (degree of polymerization: approximately 1,000 to 2,000) manufactured by Wako Pure Chemical Industries, Ltd., and the like.

The content of the thickener is preferably approximately 0.01% by mass to 5.0% by mass of the total mass of the coating composition.

[Amount of Solid Contents]

The concentration of the solid contents of the coating composition is preferably 1% by mass to 20% by mass, more preferably 2% by mass to 10% by mass, and still more preferably 3% by mass to 8% by mass of the total mass of the coating composition.

In a case where the concentration of the solid contents of the coating composition is set to be in the above-described range, it is possible to provide more favorable antireflection characteristics to films that are obtained from the coating composition. This is considered to be because, in a case where the concentration of the solid contents is in the above-described range, it is possible to cause the coating film of the coating composition to follow the coating surface of the base material in a uniform film thickness and obtain films having a uniform thickness with no film thickness variation.

The concentration of the solid contents in the coating composition can be adjusted using the contents of the solvent.

Meanwhile, the concentration of the solid contents of the coating composition refers to the proportion of the mass of the coating composition excluding the solvent in the total mass of the coating composition.

[pH]

The pH of the coating composition is preferably 1 to 8, more preferably 1 to 6, still more preferably 3 to 6, and particularly preferably 3 to 5 from the viewpoint of the antireflection property, the scratch resistance, and the antifouling property. In a case where the pH of the coating composition is 1 to 8, it is considered that the significant agglomeration of the specific polymer particles in the coating composition is suppressed, and thus films that are excellent in terms of the antireflection property, the scratch resistance, and the antifouling property can be obtained.

The pH of the coating composition is a value that is measured at 25° C. using a pH meter (product No.: HM-31, manufactured by DKK-TOA Corporation).

<Antireflection Film>

An antireflection film according to an embodiment of the present disclosure is an antireflection film that is a cured substance of the coating composition according to the embodiment of the present disclosure. The antireflection film according to the embodiment of the present disclosure is a cured substance of the coating composition according to the embodiment of the present disclosure and is thus excellent in terms of the antireflection property, the scratch resistance, and the antifouling property.

It is preferable that the antireflection film has holes having a hole diameter of 30 nm to 200 nm in a matrix containing silica as a main component and the outermost surface has a silica dense layer.

The hole may have a spherical shape or may be an elliptical body. In a case where the hole is an elliptical body, the average value of the long diameter and the short diameter is regarded as the hole diameter. The hole diameter can be obtained by observing a cross section of the antireflection film using a scanning electron microscope, measuring the hole diameters of 100 holes, and computing the average value.

The hole diameter of the hole is preferably 50 nm to 150 nm, more preferably 80 nm to 120 nm, and most preferably 90 nm to 110 nm. In a case where the hole diameter is small, there is a tendency that holes collapse in a firing process. On the other hand, in a case where the hole diameter is large, there is a tendency that holes opened on the outermost surface of the antireflection film are formed.

The holes are preferably present as independent holes in the matrix containing silica as a main component.

The volume fraction of the holes in the matrix containing silica as a main component is preferably 20% or more, more preferably 25% or more, and still more preferably 28% or more from the viewpoint of enhancing the antireflection property by decreasing the refractive index of the film. Meanwhile, the upper limit of the volume fraction of the holes is preferably 40% or less, more preferably 35% by mass or less, and still more preferably 33% or less from the viewpoint of the scratch resistance.

It is preferable that the antireflection film has a silica dense layer on the outermost layer and the number of holes opened on the outermost surface is 13 holes/10⁶ nm² or less. The number of holes opened on the outermost surface of the antireflection film can be obtained by observing the surface of the antireflection film using a scanning electron microscope (SEM) and measuring the number of openings having a diameter of 20 nm or more present in a 1,000 nmx1,000 nm region.

The number of holes opened on the outermost surface of the antireflection film is more preferably 5 holes/10⁶ nm² or less, still more preferably 3 holes/10⁶ nm² or less, and most preferably 1 hole/10⁶ nm² or less from the viewpoint of the antifouling property.

The thickness of the silica dense layer is preferably 5 nm to 40 nm. From the viewpoint of the scratch resistance, the thickness of the silica dense layer is more preferably 10 nm or more and still more preferably 15 nm or more. On the other hand, from the viewpoint of enhancing the antireflection property by decreasing the refractive index, the thickness of the silica dense layer is more preferably 30 nm or less and still more preferably 25 nm or less.

The average film thickness of the antireflection film can be set to be in a range of 50 nm to 250 nm from the viewpoint of the antireflection property. In this range, the average film thickness is more preferably 80 nm to 200 nm, still more preferably 100 nm to 150 nm, and most preferably 110 nm to 140 nm from the viewpoint of obtaining a strong antireflection property.

Regarding the unevenness in the film thickness of the antireflection film, the standard deviation of the film thickness is more preferably 15 nm or less, still more preferably 10 nm or less, and most preferably 5 nm or less from the viewpoint of obtaining a favorable antireflection property.

The average film thickness and the standard deviation of the film thickness are obtained by cutting the antireflection film vertically, observing 10 places on the cut surface using a scanning electron microscope (SEM), measuring the film thicknesses at the respective observation places from ten SEM images, and computing the average value and the standard deviation. In a case where the antireflection film is formed on a base material, the above-described observation is carried out after cutting the antireflection film together with the base material. As the base material, a base material in a laminate according to an embodiment of the present disclosure described below is used.

The refractive index of the antireflection film is preferably in a range of 1.10 to 1.38, more preferably 1.15 to 1.35, and still more preferably 1.20 to 1.32. The refractive index of the antireflection film can be controlled by changing the volume fraction of the holes in the matrix of the antireflection film using the mixing ratio between the siloxane resin and the polymer particles.

The arithmetic average roughness (Sa) of the outermost surface of the antireflection film is preferably 3.0 nm or less, more preferably 2.5 nm or less, and still more preferably 2 nm or less. The arithmetic average roughness (Sa) can be obtained by scanning a 1 μm² surface of a specimen using a scanning-type probe microscope (manufactured by Seiko Instruments Inc., SPA 300) in an interatomic force microscope DFM mode.

The antireflection property of the antireflection film is indicated by a change (AR) in the average reflectivity. The antireflection film according to the present disclosure is an antireflection film in which the numerical value of the AR is a positive value.

Specifically, the reflectivity (%) of a laminate having the antireflection film formed on the base material for light rays having wavelengths of 380 nm to 1,100 nm is measured using an UV-Vis-NIR spectrometer (product No.: UV3100PC, manufactured by Shimadzu Corporation) and an integrating sphere. At the time of measuring the reflectivity, black tape (product No.: SPV-202, manufactured by Nitto Denko Corporation) is attached to a surface of the base material which becomes a rear surface (a surface on a side on which the antireflection film of the base material is not formed) in order to suppress the reflection on the rear surface of the laminate. In addition, the average reflectivity (R^{AV}, unit: %) of the laminate is computed from the reflectivity values at the respective wavelength of the measured wavelengths of 380 nm to 1,100 nm. Similarly, the reflectivity (%) of a base material on which the antireflection film is not formed for light rays having wavelengths of 380 nm to 1,100 nm is measured. In addition, the average reflectivity (R^{0AV}, unit: %) of the base material is computed from the reflectivity values at the respective wavelength of the measured wavelengths of 380 nm to 1,100 nm.

Next, a change (ΔR, unit: %) in the average reflectivity with respect to the base material on which the antireflection film is not formed is computed from the average reflectivity values R^{AV} and R^{0Av} according to Expression (a).

ΔR=R^{0AV}−R^{Av} Expression (a)

A larger positive numerical value of ΔR indicates a more favorable antireflection (AR) property.

ΔR of the antireflection film is preferably 2.0% or more, more preferably 2.4% or more, and still more preferably 2.8% or more from the viewpoint of the antireflection property.

<Laminate>

The laminate according to the embodiment of the present disclosure has a base material and the antireflection film according to the embodiment of the present disclosure. The laminate has the above-described antireflection film and is thus excellent in terms of the antireflection property and is also excellent in terms of the scratch resistance and the antifouling property.

As the base material, base materials of glass, a resin, metal, ceramic, a composite material obtained by compositing at least one selected from glass, a resin, metal, or ceramic, or the like are exemplified. Among these, the base material is preferably a glass base material. In the case of using a glass base material as the base material, the condensation of a silanol group occurs not only between silanol groups that the specific siloxane resin has but also between a silanol group that the specific siloxane resin has and a silanol group on the glass surface, and thus it is possible to form a coating film having excellent adhesiveness to the base material.

The laminate according to the embodiment of the present disclosure preferably has the antireflection film according to the embodiment of the present disclosure in the outermost layer. It is considered that, in a case where the laminate according to the embodiment of the present disclosure has the antireflection film according to the embodiment of the present disclosure which is excellent in terms of the antifouling property in the outermost layer, laminates having an excellent antifouling property are obtained.

In the laminate according to the embodiment of the present disclosure, the average value (T^{AV}, unit: %) of the transmittance at individual wavelengths of 380 nm to 1,100 nm is preferably 93.8% or more, more preferably 94.0% or more, still more preferably 94.2% or more, and particularly preferably 94.4% or more.

The average transmittance (T^{AV}, unit: %) of the laminate is computed by averaging the values of transmittance at wavelengths of 380 nm to 1,100 nm measured using an UV-Vis-NIR spectrometer and an integrating sphere in intervals of 5 nm.

The laminate according to the embodiment of the present disclosure can be preferably used in uses demanding a high transmittance. Particularly, a laminate having a base material and an antireflection film formed on the base material, in which the antireflection film has holes having a hole diameter of 30 nm to 200 nm in a matrix containing silica as a main component, the number of holes having a diameter of 20 nm or more opened on the outermost surface of the antireflection film is 13 holes/10⁶ nm² or less, the average transmittance (T^{AV}) at a wavelength of 380 to 1,100 nm is 94.0% or more, and the pencil hardness measured using a method described in JIS K-5600-5-4 (1999) is 3H or higher is preferred as a laminate that is excellent in terms of all of an antireflection property, scratch resistance, and an antifouling property.

As a manufacturing method for obtaining the antireflection film according to the embodiment of the present disclosure, a manufacturing method of an embodiment described below in detail can be preferably used. That is, the antireflection film according to the embodiment of the present disclosure can be obtained by at least a film-forming step, a drying step, and a firing step in the manufacturing method of the embodiment described below in detail. In addition, the laminate according to the embodiment of the present disclosure can be obtained as a structure of a laminate form of a base material and the antireflection film according to the embodiment of the present disclosure using the manufacturing method of the present embodiment. Hereinafter, the manufacturing method of the present embodiment will be described in detail.

<Method for Manufacturing Antireflection Film>

A method for manufacturing an antireflection film according to an embodiment of the present disclosure has a step of forming a coating film by applying the coating composition according to the embodiment of the present disclosure onto a base material (hereinafter, also referred to as “film-forming step”), a step of drying the coating film formed by application (hereinafter, also referred to as “drying step”), and a step of firing the dried coating film (hereinafter, also referred to as “firing step”).

The coating composition according to the embodiment of the present disclosure is used at the time of manufacturing an antireflection film, and thus antireflection films (or laminates) that are excellent in terms of the antireflection property, the scratch resistance, and the antifouling property are obtained.

The method for manufacturing an antireflection film according to the embodiment of the present disclosure may also have other steps such as a cleaning step, a surface treatment step, and a cooling step as necessary.

(Film-Forming Step)

In the film-forming step, the coating composition according to the embodiment of the present disclosure is applied onto a base material, thereby forming a coating film.

In the film-forming step, as described above, the coating composition of the embodiment of the present disclosure which makes the distribution of holes that are formed in the antireflection film uniform and includes the specific polymer particles and the specific siloxane resin is used, and thus an antireflection film (or a laminate) formed by at least the drying step and the firing step described below becomes an antireflection film (or a laminate) that is excellent in terms of the antireflection property, the scratch resistance, and the antifouling property.

The amount of the coating composition applied is not particularly limited and can be appropriately set in consideration of the concentration of the solid contents of the coating composition, a desired film thickness, and the like. The amount of the coating composition applied is preferably 0.1 mL/m² to 10 mL/m², more preferably 0.5 mL/m² to 10 mL/m², and still more preferably 0.5 mL/m² to 5 mL/m². In a case where the amount of the coating composition applied is in the above-described range, the application accuracy becomes favorable, and it is possible to form films that are superior in terms of the antireflection property.

A method for applying the coating composition onto the base material is not particularly limited. As the application method, a well-known application method such as spray coating, brush coating, roller coating, bar coating, or dip coating can be appropriately selected.

(Drying Step)

The drying step is a step of drying the coating film formed by application in the film-forming step.

In the drying step, it is preferable to fix the coating film onto the base material by removing the solvent in the coating composition.

The removal of the solvent in the coating composition forms a dense film. In a case where the coating composition includes inorganic particles such as silica particles, the inorganic particles are densely disposed in the film, and a denser film is formed. It is considered that, in a case where the film becomes dense and the hardness increases, excellent scratch resistance can be obtained. In addition, it is considered that, in a case where the film becomes dense and the film surface becomes flat, the attachment of a contaminant becomes difficult, and the antifouling property is also excellent.

The coating film may be dried at room temperature (25° C.) or may be dried using a heating device.

The heating device is not particularly limited as long as the coating film can be heated to an intended temperature, and any of well-known heating devices can be used. As the heating device, in addition to an oven, an electric furnace and the like, it is possible to use a heating device that is uniquely produced in accordance with a manufacturing line.

The coating film may be dried by, for example, heating the coating film at an atmosphere temperature of 40° C. to 200° C. using the heating device. In the case of drying the coating film by heating, the heating time can be set to, for example, approximately one minute to 30 minutes.

The drying condition of the coating film is preferably a drying condition in which the coating film is heated at an atmosphere temperature of 40° C. to 200° C. for one minute to 10 minutes and more preferably a drying condition in which the coating film is heated at an atmosphere temperature of 100° C. to 180° C. for one minute to 5 minutes.

(Firing Step)

The method for manufacturing an antireflection film according to the embodiment of the present disclosure further has a step of firing the dried coating film (firing step) after the above-described drying step.

In the firing step, the coating film is preferably fired at an atmosphere temperature of 400° C. to 800° C. In a case where the dried coating film is fired at 400° C. to 800° C., the hardness of a dense film formed in the drying step further increases, and the scratch resistance further improves. Furthermore, at least some of an organic component in the coating film, particularly, the specific polymer particles are thermally decomposed and lost by firing, and holes of random sizes are partially formed in the fired film, and it is possible to effectively improve the antireflection property.

The coating film can be fired using a heating device. The heating device is not particularly limited as long as the heating device is capable of heating the coating film to an intended temperature. As the heating device, in addition to an electric furnace and the like, it is possible to use a firing device that is uniquely produced in accordance with a manufacturing line.

The firing temperature (atmosphere temperature) of the coating film is more preferably 450° C. to 800° C., still more preferably 500° C. to 750° C., and particularly preferably 600° C. to 750° C. The firing time is preferably one minute to 10 minutes and more preferably one minute to 5 minutes.

(Other Steps)

The method for manufacturing an antireflection film according to the embodiment of the present disclosure may include steps other than the respective steps described above as necessary.

As the other steps, a cleaning step, a surface treatment step, a cooling step, and the like are exemplified.

<Solar Cell Module>

A solar cell module according to an embodiment of the present disclosure comprises the laminate according to the embodiment of the present disclosure (that is, the laminate having the base material and the antireflection film according to the embodiment of the present disclosure).

The solar cell module may be configured by disposing a solar cell element that converts the light energy of sunlight into an electric energy between the laminate according to the embodiment of the present disclosure which is disposed on a sunlight incident side and a back sheet for a solar cell which is represented by a polyester film. A portion between the laminate according to the embodiment of the present disclosure and the back sheet for a solar cell such as a polyester film is sealed with, for example, a sealing material represented by a resin such as an ethylene-vinyl acetate copolymer or the like.

It is considered that the solar cell module of the embodiment of the present disclosure comprises the laminate having the antireflection film and is thus excellent in terms of the antireflection property and the scratch resistance, and thus the degradation of the light-transmitting property caused by scratches generated on the surface of the film in the case of using the solar cell module for a long period of time is suppressed, and the power generation efficiency is excellent.

The solar cell module according to the embodiment of the present disclosure preferably comprises the laminate according to the embodiment of the present disclosure in the outermost layer of the solar cell module. That is, the outermost layer of the solar cell module according to the embodiment of the present disclosure is preferably an antireflection film. Even in a case in which the solar cell module of the embodiment of the present disclosure has an antireflection film as the outermost layer, the antireflection film according to the embodiment of the present disclosure has an antifouling property enabling the easy removal of a resin such as a sealing material, and thus an excellent manufacturing efficiency in the assembly step can be obtained.

Members other than the laminate and the back sheet in the solar cell module are described in detail in, for example, “Configurational materials of photovoltaic power generation systems” (edited by Eiichi Sugimoto, published by Kogyo Chosakai Publishing Co., Ltd. in 2008). The solar cell module preferably comprises the laminate according to the embodiment of the present disclosure on the sunlight incident side, and the configurations other than the laminate according to the embodiment of the present disclosure are not limited.

The base material of the solar cell module, which is disposed on the sunlight incident side, is preferably the base material of the laminate according to the embodiment of the present disclosure, and examples of the base material include base materials of glass, a resin, metal, ceramic, a composite material obtained by compositing at least one selected from glass, a resin, metal, or ceramic, or the like. A preferred base material is a glass base material.

The solar cell element that is used in the solar cell module is not particularly limited. To the solar cell module, it is possible to apply any of a variety of well-known solar cell elements such as silicon-based solar cell elements of single-crystal silicon, polycrystal silicon, amorphous silicon, or the like, II-V group or II-VI group compound semiconductor-based solar cell elements of copper-indium-gallium-selenium, copper-indium-selenium, cadmium-tellurium, gallium-arsenic, or the like.

### EXAMPLES

Hereinafter, the embodiments of the present invention will be described in detail using examples, but the present invention is not limited to the following examples. Meanwhile, unless particularly otherwise described, “parts” is mass-based. “Mw” is an abbreviation of the weight-average molecular weight.

Synthesis of Polymer Particles

Polymer particles were synthesized according to Synthesis Example 1-1 to Synthesis Example 1-9.

### Synthesis Example 1-1

A liquid mixture having a composition described below was stirred and emulsified using a homogenizer at 10,000 rpm (round per minute, which will also be true below) for five minutes under cooling, thereby obtaining an emulsified liquid (64.8 parts by mass).

[Composition of Liquid Mixture]

Ion exchange water: 35 parts by mass

Methyl methacrylate: 13.8 parts by mass

n-Butyl acrylate: 13.8 parts by mass

Methoxy polyethylene glycol methacrylate (n=9): 0.6 parts by mass

Diethylene glycol dimethacrylate: 0.6 parts by mass

Nonionic reactive emulsifier having ethylene oxide chain (trade name: LATEMUL PD-450 (main component: polyoxyalkylene alkenyl ether), manufactured by KAO Corporation): 0.4 parts by mass

Polymerization initiator (trade name: V-65, manufactured by Wako Pure Chemical Industries, Ltd.): 0.6 parts by mass

Meanwhile, ion exchange water (35 parts by mass) and the nonionic reactive emulsifier having an ethylene oxide chain (trade name: LATEMUL PD-450 (main component: polyoxyalkylene alkenyl ether), manufactured by KAO Corporation) (0.2 parts by mass) were put into a reactor comprising a stirring device, a reflux cooler, a thermometer, and a nitrogen gas blowing tube, the temperature was increased to 65° C., and then the atmosphere was substituted with nitrogen.

The emulsified liquid was uniformly added dropwise in a nitrogen atmosphere for three hours while maintaining the temperature at 65° C., and the components were reacted at 65° C. for two hours.

After the end of the reaction, the reaction product was cooled, thereby obtaining an aqueous emulsion having a concentration of solid contents of 30% by mass and an average primary particle diameter of 100 nm (polymer particles-1).

### Synthesis Example 1-2

An aqueous emulsion having a concentration of solid contents of 30% by mass and an average primary particle diameter of 35 nm was obtained in the same manner as in Synthesis Example 1-1 except for the fact that the rotation speed of the homogenizer was set to 21,000 rpm (polymer particles-2).

### Synthesis Example 1-3

An aqueous emulsion having a concentration of solid contents of 30% by mass and an average primary particle diameter of 55 nm was obtained in the same manner as in Synthesis Example 1-1 except for the fact that the rotation speed of the homogenizer was set to 18,000 rpm (polymer particles-3).

### Synthesis Example 1-4

An aqueous emulsion having a concentration of solid contents of 30% by mass and an average primary particle diameter of 63 nm was obtained in the same manner as in Synthesis Example 1-1 except for the fact that the rotation speed of the homogenizer was set to 16,000 rpm (polymer particles-4).

### Synthesis Example 1-5

An aqueous emulsion having a concentration of solid contents of 30% by mass and an average primary particle diameter of 130 nm was obtained in the same manner as in Synthesis Example 1-1 except for the fact that the rotation speed of the homogenizer was set to 6,000 rpm (polymer particles-5).

### Synthesis Example 1-6

An aqueous emulsion having a concentration of solid contents of 30% by mass and an average primary particle diameter of 180 nm was obtained in the same manner as in Synthesis Example 1-1 except for the fact that the rotation speed of the homogenizer was set to 3,000 rpm (polymer particles-6).

### Synthesis Example 1-7

### Polymer Particles for Comparison

An aqueous emulsion having a concentration of solid contents of 30% by mass and a number-average primary particle diameter of 2 nm was obtained using a method described in Example 2 of JP4512250B (polymer particles-7).

### Synthesis Example 1-8

### Polymer Particles for Comparison

An aqueous emulsion having a concentration of solid contents of 30% by mass and an average primary particle diameter of 230 nm was obtained in the same manner as in Synthesis Example 1-1 except for the fact that the rotation speed of the homogenizer was set to 350 rpm (polymer particles-8).

### Synthesis Example 1-9

An aqueous emulsion having a concentration of solid contents of 40% by mass and an average primary particle diameter of 100 nm was obtained in the same manner as in Synthesis Example 1 except for the fact that the rotation speed of the homogenizer was set to 16,000 rpm, an anionic reactive emulsifier having an ethylene oxide chain (trade name: ADEKA REASOAP SR-1025 (main component: ether sulfate-type ammonium salt), manufactured by ADEKA Corporation) was used, and the amount of the ion exchange water was adjusted so that the concentration of the solid contents reached 40% by mass (polymer particles-9).

### Synthesis Example 1-10

The aqueous emulsion (polymer particles 1) prepared in Synthesis Example 1-1 was condensed, thereby obtaining an aqueous emulsion having a concentration of solid contents of 60% by mass (polymer particles-10).

Synthesis of Siloxane Resin

A siloxane resin-1 to a siloxane resin-13 were synthesized according to Synthesis Examples 2-1 to 2-13 described below.

Meanwhile, the details of individual units included in the respective synthesized siloxane resins are as described below.

Siloxane Resins-1, 2, 3, 4, 5, 6, 8, 9, and 11

An R¹—Si(OR²)₂O_{1/2} unit, an R¹—Si(OR²)O_{2/2} unit, and an R¹—Si—O_{3/2} unit are included. (R′: a methyl group, R²: a hydrogen atom and/or an ethyl group)

Siloxane Resins-7 and 13

An R¹—Si(OR²)₂O_{1/2} unit, an R¹—Si(OR²)O_{2/2} unit, and an R¹—Si—O_{3/2} unit, a Si(OR²)₃O_{1/2} unit, a Si(OR²)₂O_{2/2} unit, a Si—(OR²)O_{3/2} unit, a Si—O₄₁₂unit are included. (R′: a methyl group, R²: a hydrogen atom and/or an ethyl group)

Siloxane Resins-10 and 12

An R¹—Si(OR²)₂O_{1/2} unit, an R¹—Si(OR²)O_{2/2} unit, and an R¹—Si—O_{3/2} unit are included. (R′: a phenyl group, R²: a hydrogen atom and/or a methyl group)

### Synthesis Example 2-1

Sodium carbonate (12.7 g, 0.12 mol) and water (80 mL) were injected into and stirred in a reaction container comprising a reflux cooling tube, a dropping funnel, and a stirrer, and methyl isobutyl ketone (80 mL) was added thereto. The stirring rate was set to be slow enough to hold an organic layer and water layer. Next, methyltrichlorosilane (14.9 g, 0.1 mol) was slowly added dropwise from the dropping funnel for 30 minutes. The temperature of the reaction mixture at this time was increased up to 60° C. Furthermore, the reaction mixture was heated and stirred on an oil bath at 60° C. for 24 hours. After the end of the reaction, the organic layer was cleaned with cleaning water until the organic layer became neutral, and then the organic layer was dried using a drying agent. After the removal of the drying agent, the solvent was distilled away at a reduced pressure, and the organic layer was dried in a vacuum overnight, thereby obtaining a siloxane resin-1 in a white solid form.

The weight-average molecular weight of the obtained siloxane resin-1 was measured using the above-described method and turned out to be Mw=2,850.

The content of the specific unit in the siloxane resin-1 was 100% by mass.

### Synthesis Example 2-2

A siloxane resin-2 was obtained in a white solid form in the same manner as in Synthesis Example 2-1 except for the fact that, in a reaction system in which the same organic layer and water layer as in Synthesis Example 2-1 formed two layers, potassium hydroxide (13.5 g, 0.24 mol) was used instead of sodium carbonate, and a reaction was caused using water (80 mL), methyl isobutyl ketone (80 mL), and methyltrichlorosilane (14.9 g, 0.1 mol).

The weight-average molecular weight of the obtained siloxane resin-2 was measured using the above-described method and turned out to be Mw=1,900.

The content of the specific unit in the siloxane resin-2 was 100% by mass.

### Synthesis Example 2-3

A siloxane resin-3 was obtained in a white solid form in the same manner as in Synthesis Example 2-1 except for the fact that, in Synthesis Example 2-1, tetrahydrofuran (80 mL) was used as the organic solvent, and a reaction was caused using sodium carbonate (12.7 g, 0.12 mol), water (80 mL), and methyltrichlorosilane (14.9 g, 0.1 mol). During the reaction, the organic layer and the water layer formed two layers in the same manner as in Synthesis Example 2-1.

The weight-average molecular weight of the obtained siloxane resin-3 was measured using the above-described method and turned out to be Mw=5,900.

The content of the specific unit in the siloxane resin-3 was 100% by mass.

### Synthesis Example 2-4

A siloxane resin-4 was obtained in a white solid form in the same manner as in Synthesis Example 2-1 except for the fact that, in a reaction system in which the same organic layer and water layer as in Synthesis Example 2-1 formed two layers, a reaction was caused using sodium carbonate (15.9 g, 0.15 mol), water (80 mL), methyl isobutyl ketone (80 mL), and methyltrichlorosilane (14.9 g, 0.1 mol).

The weight-average molecular weight of the obtained siloxane resin-4 was measured using the above-described method and turned out to be Mw=3,350.

The content of the specific unit in the siloxane resin-4 was 100% by mass.

### Synthesis Example 2-5

A siloxane resin-5 was obtained in a white solid form in the same manner as in Synthesis Example 2-2 except for the fact that, in Synthesis Example 2-2, methyltrichlorosilane was changed to methyltriethoxysilane.

The siloxane resin-5 was a partially hydrolyzed oligomer of methylethoxysilane. The weight-average molecular weight of the obtained siloxane resin-5 was measured using the above-described method and turned out to be Mw=1,450.

The content of the specific unit in the siloxane resin-5 was 100% by mass.

### Synthesis Example 2-6

A siloxane resin-6 was obtained in a white solid form in the same manner as in Synthesis Example 2-1 except for the fact that, in a reaction system in which the same organic layer and water layer as in Synthesis Example 2-1 formed two layers, 1-butanol (80 mL) was used as the organic solvent, a reaction was caused using sodium carbonate (12.7 g, 0.12 mol), water (80 mL), and methyltrichlorosilane (14.9 g, 0.1 mol), and the reaction after the dropwise addition of the chlorosilane was caused at 30° C. for two hours.

The weight-average molecular weight of the obtained siloxane resin-6 was measured using the above-described method and turned out to be Mw=770.

The content of the specific unit in the siloxane resin-6 was 100% by mass.

### Synthesis Example 2-7

A siloxane resin-7 was obtained in a white solid form in the same manner as in Synthesis Example 2-2 except for the fact that, in Synthesis Example 2-2, methyltrichlorosilane was changed to tetraethoxysilane (3% by mass) and methyltriethoxysilane (97% by mass).

The weight-average molecular weight of the obtained siloxane resin-7 was measured using the above-described method and turned out to be Mw=5,500.

The content of the specific unit in the siloxane resin-7 was 97% by mass.

### Synthesis Example 2-8

A siloxane resin-8 was obtained in a white solid form in the same manner as in Synthesis Example 2-1 except for the fact that, in the same reaction order as in Synthesis Example 2-1, a method in which methyltrichlorosilane (14.9 g, 0.1 mol) was dissolved in methyl isobutyl ketone (20 mL) and added dropwise to a mixture of sodium carbonate (12.7 g, 0.12 mol), water (80 mL), and methyl isobutyl ketone (60 mL) in the reaction container in a reaction of high-speed stirring preventing an organic phase and a water phase from forming two layers was used.

The weight-average molecular weight of the obtained siloxane resin-8 was measured using the above-described method and turned out to be Mw=580.

The content of the specific unit in the siloxane resin-8 was 100% by mass.

### Synthesis Example 2-9

A siloxane resin-9 was obtained in a white solid form in the same manner as in Synthesis Example 2-1 except for the fact that, in a reaction system in which the organic layer and the water layer of Synthesis Example 2-1 formed two layers, without using a base or the like, a reaction was caused using water (80 mL), methyl isobutyl ketone (80 mL), and methyltrichlorosilane (14.9 g, 0.1 mol).

The weight-average molecular weight of the obtained siloxane resin-9 was measured using the above-described method and turned out to be Mw=6800.

The content of the specific unit in the siloxane resin-9 was 100% by mass.

### Synthesis Example 2-10

Ethanol (81.35 g), water (11.76 g), a nitric acid aqueous solution (concentration: 60% by mass), and phenyltrimethoxysilane (6.68 g) were mixed and dissolved together, thereby preparing a raw material liquid. A hydrolysis treatment was carried out by heating the raw material liquid up to 25° C. and stirring the raw material liquid for one hour, thereby obtaining a solution of a siloxane resin-10.

The weight-average molecular weight of the siloxane resin-10 included in the obtained solution was measured using the above-described method and turned out to be Mw=400.

The siloxane resin-10 was a siloxane resin not including the specific unit.

### Synthesis Example 2-11

A solution of a siloxane resin-11 was obtained in the same manner as in Synthesis Example 2-10 except for the fact that, in Synthesis Example 2-10, phenyltrimethoxysilane was changed to methyltriethoxysilane.

The weight-average molecular weight of the siloxane resin-11 included in the obtained solution was measured using the above-described method and turned out to be Mw=310.

The content of the specific unit in the siloxane resin-11 was 100% by mass.

### Synthesis Example 2-12

A siloxane resin-12 was obtained in a white solid form in the same manner as in Synthesis Example 2-9 except for the fact that, in Synthesis Example 2-9, methyltrichlorosilane was changed to phenyltrimethoxysilane.

The weight-average molecular weight of the obtained siloxane resin-12 was measured using the above-described method and turned out to be Mw=1,250.

The siloxane resin-12 was a siloxane resin not including the specific unit.

### Synthesis Example 2-13

A siloxane resin-13 was obtained in a white solid form in the same manner as in Synthesis Example 2-10 except for the fact that, in Synthesis Example 2-10, phenyltrimethoxysilane was changed to tetraethoxysilane (10% by mass) and methyltriethoxysilane (90% by mass).

The weight-average molecular weight of the obtained siloxane resin-13 was measured using the above-described method and turned out to be Mw=2,300.

The content of the specific unit in the siloxane resin-13 was 90% by mass.

### Example 1

(Preparation of Coating Fluid)

A water dispersion of specific polymer particles (polymer particles 1, nonionic polymer particles, number-average primary particle diameter: 100 nm, concentration of solid contents: 30% by mass) (1.7 parts by mass), a siloxane resin 1 (specific siloxane resin, weight-average molecular weight: 2,850) (2.0 parts by mass), a 20% by mass aqueous solution of acetic acid (pKa: 4.76) (0.2 parts by mass), water (3.3 parts by mass), and 2-propanol (62 parts by mass) were mixed and stirred together, thereby preparing a coating fluid (coating composition).

The concentration of solid contents of the coating fluid was 3.7% by mass. Meanwhile, the concentration of the solid contents of the coating fluid is the proportion of the total amount of the coating fluid excluding water and an organic solvent in the total mass of the coating fluid.

The mass ratio (% by mass) of water to 2-propanol (organic solvent) in the solvent in the coating fluid is 7/93. The solvent in the coating fluid consists of water and 2-propanol (organic solvent).

The proportion of the mass of the specific polymer particles in the SiO₂-equivalent mass of the siloxane resin-1 was 0.4.

In addition, the pH (25° C.) of the coating fluid was measured using a pH meter (product No.: HM-31, manufactured by DKK-TOA Corporation) and found out to be pH=5.

(Production of Laminate Having Antireflection Film)

The prepared coating fluid was applied using a roll coater to a surface of a 3 mm-thick figured glass base material (average transmittance: 91.8%) having a protrusion and recess structure with an arithmetic average roughness Ra of 0.4 μm on a surface, thereby forming a coating film. Meanwhile, the arithmetic average roughness Ra of the figured glass base material was measured using a surface roughness meter (product No.: HANDYSURF E-35B, manufactured by Tokyo Seimitsu Co., Ltd.) according to JIS-B0601.

Next, the coating film formed on the surface of the base material was heated and dried at an atmosphere temperature of 100° C. for one minute using an oven. Furthermore, the dried coating film was fired at an atmosphere temperature of 700° C. for three minutes using an electric furnace, thereby producing a laminate having an antireflection film on the surface of the base material. Meanwhile, the antireflection film formed on the glass surface of the base material was produced by adjusting the amount applied so that the average film thickness reached 130 nm.

The average film thickness of the antireflection film was confirmed by cutting the laminate having the antireflection film in a direction perpendicular to the base material, observing 10 places on the cut surface using a scanning electron microscope (SEM), measuring the film thicknesses at the respective observation places from ten SEM images, and computing the average value thereof.

The hole diameter computed by measuring the diameters and short diameters of 100 holes in the above-described cross-sectional SEM image respectively and averaging the values was 93 nm.

In addition, as a result of observing the surface of the laminate having the antireflection film using a scanning electron microscope (SEM), the number of holes having a diameter of 20 nm or more opened on the outermost surface was 0 holes/10⁶ nm².

### Example 2 to Example 28 and Comparative Example 1 to Comparative Example 8

Coating fluids were prepared in the same manner as in Example 1 except for the fact that, in Example 1, the types and the amounts blended of compounds in coating compositions were changed as shown in Table 1, Table 2, and Table 3, and laminates having an antireflection film were produced in the same manner as in Example 1.

### Example 29

A laminate having an antireflection film was produced in the same manner as in Example 1 except for the fact that the glass base material was changed to a 3 mm-thick glass base material (arithmetic average roughness Ra=0.07 μm) having a flat surface.

The average film thicknesses of the antireflection films in Example 2 to Example 29 and Comparative Example 1 to Comparative Example 8 were all “130 nm” as in Example 1.

The concentrations (% by mass) of solid contents of the respective coating fluids prepared are as shown in the column of the concentration (% by mass) in Table 1, Table 2, and Table 3.

Numerical values in Table 1, Table 2, and Table 3 indicate the contents (parts by mass) of the respective components in the respective coating fluids.

In Table 1, Table 2, and Table 3, the sign “-” in the columns of the contents of the respective components indicates that the corresponding component is not contained.

The proportions of the mass of the specific polymer particles in the SiO₂-equivalent mass of the siloxane resin are as shown in Table 4, Table 5, and Table 6.

The solvents in the respective coating fluids were made up of water and 2-propanol (IPA, organic solvent) or water, IPA, and 1-methoxy-2-propanol (PGME, organic solvent having a high boiling point). The mass ratios (% by mass) between water and the organic solvent in the examples and the comparative examples are as shown in Table 4, Table 5, and Table 6.

The ratios of PGME to all of the solvent in Examples 26 to 28 are as shown in Table 5.

TABLE 1

| | Polymer particles (particle diameter) | | | | | | | | Siloxane resin (Mw) | |
|---|---|---|---|---|---|---|---|---|---|---|
| | Variety | | | | | | | | | |
| | Polymer | Polymer | Polymer | Polymer | Polymer | Polymer | Polymer | Polymer | Siloxane | Siloxane |
| | particle-1 | particle-2 | particle-3 | particle-4 | particle-5 | particle-6 | particle-9 | particle-10 | resin-1 | resin-2 |
| | (100 nm) | (35 nm) | (55 nm) | (63 nm) | (130 nm) | (180 nm) | (100 nm) | (100 nm) | (Mw: 2850) | (Mw: 1900) |
| (% by mass) | 30 | 30 | 30 | 30 | 30 | 3030 | 30 | 60 | 100 | 100 |
| Example 1 | 1.7 | — | — | — | — | — | — | — | 2.0 | — |
| Example 2 | 1.7 | — | — | — | — | — | — | — | — | 2.0 |
| Example 3 | 1.7 | — | — | — | — | — | — | — | — | — |
| Example 4 | 1.7 | — | — | — | — | — | — | — | — | — |
| Example 5 | 1.7 | — | — | — | — | — | — | — | — | — |
| Example 6 | 1.7 | — | — | — | — | — | — | — | — | — |
| Example 7 | 1.7 | — | — | — | — | — | — | — | — | — |
| Example 8 | — | 1.7 | — | — | — | — | — | — | 2.0 | — |
| Example 9 | — | — | 1.7 | — | — | — | — | — | 2.0 | — |
| Example 10 | — | — | — | 1.7 | — | — | — | — | 2.0 | — |
| Example 11 | — | — | — | — | 1.7 | — | — | — | 2.0 | — |
| Example 12 | — | — | — | — | — | 1.7 | — | — | 2.0 | — |

| | Siloxane resin (Mw) | | | | | Solvent | | | Acid | |
|---|---|---|---|---|---|---|---|---|---|---|
| | Variety | | | | | | | | | |
| | Siloxane | Siloxane | Siloxane | Siloxane | Siloxane | | | | Acetic | Nitric |
| | resin-3 | resin-4 | resin-5 | resin-6 | resin-7 | | | | acid | acid |
| | (Mw: 5900) | (Mw: 3350) | (Mw: 1450) | (Mw: 770) | (Mw: 5500) | Water | IPA | PGME | (pKa: 4.76) | (pKa: −1.4 |
| (% by mass) | 100 | 100 | 100 | 100 | 100 | — | — | — | 20 | 40 |
| Example 1 | — | — | — | — | — | 3.3 | 62 | — | 0.2 | — |
| Example 2 | — | — | — | — | — | 3.3 | 62 | — | 0.2 | — |
| Example 3 | 2.0 | — | — | — | — | 3.3 | 62 | — | 0.2 | — |
| Example 4 | — | 2.0 | — | — | — | 3.3 | 62 | — | 0.2 | — |
| Example 5 | — | — | 2.0 | — | — | 3.3 | 62 | — | 0.2 | — |
| Example 6 | — | — | — | 2.0 | — | 3.3 | 62 | — | 0.2 | — |
| Example 7 | — | — | — | — | 2.0 | 3.3 | 62 | — | 0.2 | — |
| Example 8 | — | — | — | — | — | 3.3 | 62 | — | 0.2 | — |
| Example 9 | — | — | — | — | — | 3.3 | 62 | — | 0.2 | — |
| Example 10 | — | — | — | — | — | 3.3 | 62 | — | 0.2 | — |
| Example 11 | — | — | — | — | — | 3.3 | 62 | — | 0.2 | — |
| Example 12 | — | — | — | — | — | 3.3 | 62 | — | 0.2 | — |

TABLE 2

| | Polymer particles (particle diameter) | | | | | | | | Siloxane resin (Mw) | |
|---|---|---|---|---|---|---|---|---|---|---|
| | Variety | | | | | | | | | |
| | Polymer | Polymer | Polymer | Polymer | Polymer | Polymer | Polymer | Polymer | Siloxane | Siloxane |
| | particle-1 | particle-2 | particle-3 | particle-4 | particle-5 | particle-6 | particle-9 | particle-10 | resin-1 | resin-2 |
| | (100 nm) | (35 nm) | (55 nm) | (63 nm) | (130 nm) | (180 nm) | (100 nm) | (100 nm) | (Mw: 2850) | (Mw: 1900) |
| Concentration | 30 | 30 | 30 | 30 | 30 | 30 | 30 | 60 | 100 | 100 |
| (% by mass) | | | | | | | | | | |
| Example 13 | 0.91 | — | — | — | — | — | — | — | 2.2 | — |
| Example 14 | — | — | — | — | — | — | — | 1.5 | 1.6 | — |
| Example 15 | — | — | — | — | — | — | — | 1.8 | 1.4 | — |
| Example 16 | — | — | — | — | — | — | — | 0.15 | 2.3 | — |
| Example 17 | — | — | — | — | — | — | — | 0.85 | 2.0 | — |
| Example 18 | — | — | — | — | — | — | — | 0.85 | 2.0 | — |
| Example 19 | — | — | — | — | — | — | — | 0.85 | 2.0 | — |
| Example 20 | — | — | — | — | — | — | — | 0.85 | 2.0 | — |
| Example 21 | 1.7 | — | — | — | — | — | — | — | 2.0 | — |
| Example 22 | 1.7 | — | — | — | — | — | — | — | 2.0 | — |
| Example 23 | 1.7 | — | — | — | — | — | — | — | 2.0 | — |
| Example 24 | — | — | — | — | — | — | 1.7 | — | 2.0 | — |
| Example 25 | 1.7 | — | — | — | — | — | — | — | 2.0 | — |
| Example 26 | 1.7 | — | — | — | — | — | — | — | 2.0 | — |
| Example 27 | 1.7 | — | — | — | — | — | — | — | 2.0 | — |
| Example 28 | 1.7 | — | — | — | — | — | — | — | 2.0 | — |
| Example 29 | 1.7 | — | — | — | — | — | — | — | 2.0 | — |

| | Siloxane resin (Mw) | | | | | Solvent | | | Acid | |
|---|---|---|---|---|---|---|---|---|---|---|
| | Variety | | | | | | | | | |
| | Siloxane | Siloxane | Siloxane | Siloxane | Siloxane | | | | Acetic | Nitric |
| | resin-3 | resin-4 | resin-5 | resin-6 | resin-7 | | | | acid | acid |
| | (Mw: 5900) | (Mw: 3350) | (Mw: 1450) | (Mw: 770) | (Mw: 5500) | Water | IPA | PGME | (pKa: 4.76) | (pKa: −1.4 |
| Concentration | 100 | 100 | 100 | 100 | 100 | — | — | — | 20 | 40 |
| (% by mass) | | | | | | | | | | |
| Example 13 | — | — | — | — | — | 3.8 | 60 | — | 0.2 | — |
| Example 14 | — | — | — | — | — | 3.8 | 61 | — | 0.2 | — |
| Example 15 | — | — | — | — | — | 3.7 | 61 | — | 0.2 | — |
| Example 16 | — | — | — | — | — | 4.3 | 59 | — | 0.2 | — |
| Example 17 | — | — | — | — | — | 11.2 | 153 | — | 0.2 | — |
| Example 18 | — | — | — | — | — | 1.08 | 21 | — | 0.2 | — |
| Example 19 | — | — | — | — | — | 0.3 | 10.6 | — | 0.2 | — |
| Example 20 | — | — | — | — | — | 0.2 | 9 | — | 0.2 | — |
| Example 21 | — | — | — | — | — | 18.2 | 46 | — | 0.2 | — |
| Example 22 | — | — | — | — | — | 31.2 | 33 | — | 0.2 | — |
| Example 23 | — | — | — | — | — | 51.2 | 13 | — | 0.2 | — |
| Example 24 | — | — | — | — | — | 3.3 | 62 | — | 0.2 | — |
| Example 25 | — | — | — | — | — | 3.3 | 63 | — | 0.2 | 0.15 |
| Example 26 | — | — | — | — | — | 3.3 | 60.7 | 1.3 | 0.2 | — |
| Example 27 | — | — | — | — | — | 3.3 | 55.8 | 6.2 | 0.2 | — |
| Example 28 | — | — | — | — | — | 3.3 | 49.6 | 12.4 | 0.2 | — |
| Example 29 | — | — | — | — | — | 3.3 | 62 | — | 0.2 | — |

TABLE 3

| | Polymer particles (particle diameter) | | | Siloxane resin (Mw) | | | |
|---|---|---|---|---|---|---|---|
| | Variety | | | | | | |
| | Polymer | Polymer | Polymer | Siloxane | Siloxane | Siloxane | Siloxane |
| | particles-1 | particles-7 | particles-8 | resin-1 | resin-8 | resin-9 | resin-10 |
| | (100 nm) | (2 nm) | (230 nm) | (Mw: 2850) | (Mw: 580) | (MW: 6800) | (MW: 400) |
| Concentration | 30 | 30 | 30 | 100 | 100 | 100 | 100 |
| (% by mass) | | | | | | | |
| Comparative | 1.7 | — | — | — | 2.0 | — | — |
| Example 1 | | | | | | | |
| Comparative | 1.7 | — | — | — | — | 2.0 | — |
| Example 2 | | | | | | | |
| Comparative | 1.7 | — | — | — | — | — | 2.0 |
| Example 3 | | | | | | | |
| Comparative | 1.7 | — | — | — | — | — | — |
| Example 4 | | | | | | | |
| Comparative | 1.7 | — | — | — | — | — | — |
| Example 5 | | | | | | | |
| Comparative | 1.7 | — | — | — | — | — | — |
| Example 6 | | | | | | | |
| Comparative | — | 1.7 | — | 2.0 | — | — | — |
| Example 7 | | | | | | | |
| Comparative | — | — | 1.7 | 2.0 | — | — | — |
| Example 8 | | | | | | | |

| | Siloxane resin (Mw) | | | Solvent | | Acid | |
|---|---|---|---|---|---|---|---|
| | Variety | | | | | | |
| | Siloxane | Siloxane | Siloxane | | | Acetic | Nitric |
| | resin-11 | resin-12 | resin-13 | | | acid | acid |
| | (Mw: 310) | (Mw: 1250) | (Mw: 2300) | Water | IPA | (pKa: 4.76) | (pKa: −1.4) |
| Concentration | 100 | 100 | 100 | — | — | 20 | 40 |
| (% by mass) | | | | | | | |
| Comparative | — | — | — | 3.3 | 59 | 0.2 | — |
| Example 1 | | | | | | | |
| Comparative | — | — | — | 3.3 | 59 | 0.2 | — |
| Example 2 | | | | | | | |
| Comparative | — | — | — | 3.3 | 59 | 0.2 | — |
| Example 3 | | | | | | | |
| Comparative | 2.0 | — | — | 3.3 | 59 | 0.2 | — |
| Example 4 | | | | | | | |
| Comparative | — | 2.0 | — | 3.3 | 59 | 0.2 | — |
| Example 5 | | | | | | | |
| Comparative | — | — | 2.0 | 3.3 | 59 | 0.2 | — |
| Example 6 | | | | | | | |
| Comparative | — | — | — | 3.3 | 59 | 0.2 | — |
| Example 7 | | | | | | | |
| Comparative | — | — | — | 3.3 | 59 | 0.2 | — |
| Example 8 | | | | | | | |

TABLE 4

| | | | | | | PGME | Weight- | | Polymer |
|---|---|---|---|---|---|---|---|---|---|
| | | | | | Water/ | ratio | average | Solid | particles/ |
| | Polymer | | | | organic | [to mass | molecular | content | siloxane |
| | particles | Siloxane | | | solvent | of all | weight of | concen- | resin |
| | (particle | resin | | | mass ratio | solvent, | siloxane | tration | (SiO₂- |
| | diameter) | (Mw) | Solvent | Acid | [% by mass] | % by mass] | resin | [% by mass] | equivalent) |
| Example 1 | Polymer | Siloxane | Water/ | Acetic acid | 7/93 | — | 2850 | 3.7 | 0.4 |
| | particles-1 | resin-1 | IPA | (pKa: 4.76) | | | | | |
| | (100 nm) | (Mw: 2850) | | | | | | | |
| Example 2 | Polymer | Siloxane | Water/ | Acetic acid | 7/93 | — | 1900 | 3.7 | 0.4 |
| | particles-1 | resin-2 | IPA | (pKa: 4.76) | | | | | |
| | (100 nm) | (Mw: 1900) | | | | | | | |
| Example 3 | Polymer | Siloxane | Water/ | Acetic acid | 7/93 | — | 5900 | 3.7 | 0.4 |
| | particles-1 | resin-3 | IPA | (pKa: 4.76) | | | | | |
| | (100 nm) | (Mw: 5900) | | | | | | | |
| Example 4 | Polymer | Siloxane | Water/ | Acetic acid | 7/93 | — | 3350 | 3.7 | 0.4 |
| | particles-1 | resin-4 | IPAA | (pKa: 4.76) | | | | | |
| | (100 nm) | (Mw: 3350) | | | | | | | |
| Example 5 | Polymer | Siloxane | Water/ | Acetic acid | 7/93 | — | 1450 | 3.7 | 0.4 |
| | particles-1 | resin-5 | IPA | (pKa: 4.76) | | | | | |
| | (100 nm) | (Mw: 1450) | | | | | | | |
| Example 6 | Polymer | Siloxane | Water/ | Acetic acid | 7/93 | — | 770 | 3.7 | 0.4 |
| | particles-1 | resin-6 | IPA | (pKa: 4.76) | | | | | |
| | (100 nm) | (Mw: 770) | | | | | | | |
| Example 7 | Polymer | Siloxane | Water/ | Acetic acid | 7/93 | — | 5500 | 3.7 | 0.4 |
| | particles-1 | resin-7 | IPA | (pKa: 4.76) | | | | | |
| | (100 nm) | (Mw: 5500) | | | | | | | |
| Example 8 | Polymer | Siloxane | Water/ | Acetic acid | 7/93 | — | 2850 | 3.7 | 0.4 |
| | particles-2 | resin-1 | IPA | (pKa: 4.76) | | | | | |
| | (35 nm) | (Mw: 2850) | | | | | | | |
| Example 9 | Polymer | Siloxane | Water/ | Acetic acid | 7/93 | — | 2850 | 3.7 | 0.4 |
| | particles-3 | resin-1 | IPA | (pKa: 4.76) | | | | | |
| | (55 nm) | (Mw: 2850) | | | | | | | |
| Example 10 | Polymer | Siloxane | Water/ | Acetic acid | 7/93 | — | 2850 | 3.7 | 0.4 |
| | particles-4 | resin-1 | IPA | (pKa: 4.76) | | | | | |
| | (63 nm) | (Mw: 2850) | | | | | | | |
| Example 11 | Polymer | Siloxane | Water/ | Acetic acid | 7/93 | — | 2850 | 3.7 | 0.4 |
| | particles-5 | resin-1 | IPA | (pKa: 4.76) | | | | | |
| | (130 nm) | (Mw: 2850) | | | | | | | |
| Example 12 | Polymer | Siloxane | Water/ | Acetic acid | 7/93 | — | 2850 | 3.7 | 0.4 |
| | particles-6 | resin-1 | IPA | (pKa: 4.76) | | | | | |
| | (180 nm) | (Mw: 2850) | | | | | | | |

| | | | Evaluation | | | | | |
|---|---|---|---|---|---|---|---|---|
| | Amount of | | | | | | | Antifouling |
| | trialkoxysi- | | | | | | | property |
| | lane unit in | | In-plane | | Average | | | (tape |
| | siloxane | | film | Antire- | transmit- | AR | Scratch | adhesive |
| | resin | | thickness | flection | tance | perfor- | resis- | deposit |
| | [% by mass] | pH | unevenness | property | [%] | mance | tance | property) |
| Example 1 | 100 | 5 | A | 5 | 94.6 | 2.9 | 4H | 5 |
| Example 2 | 100 | 5 | A | 5 | 94.6 | 2.9 | 4H | 5 |
| Example 3 | 100 | 5 | A | 5 | 94.6 | 2.9 | 3H | 4 |
| Example 4 | 100 | 5 | A | 5 | 94.6 | 2.9 | 3H | 4 |
| Example 5 | 100 | 5 | A | 5 | 94.6 | 2.9 | 2H | 5 |
| Example 6 | 100 | 5 | A | 5 | 94.6 | 2.9 | 2H | 5 |
| Example 7 | 97 | 5 | A | 5 | 94.6 | 2.9 | 3H | 4 |
| Example 8 | 100 | 5 | A | 4 | 94.4 | 2.7 | 4H | 5 |
| Example 9 | 100 | 5 | A | 4 | 94.5 | 2.8 | 4H | 5 |
| Example 10 | 100 | 5 | A | 5 | 94.6 | 2.9 | 4H | 5 |
| Example 11 | 100 | 5 | A | 4 | 94.5 | 2.8 | 3H | 4 |
| Example 12 | 100 | 5 | A | 4 | 94.4 | 2.7 | 3H | 4 |

TABLE 5

| | | | | | | | PGME | Weight- | |
|---|---|---|---|---|---|---|---|---|---|
| | | | | | | Water/ | ratio | average | Solid |
| | Polymer | | | | | organic | [to mass | molecular | content |
| | particles | Siloxane | | | | solvent | of all | weight of | concen- |
| | (particle | resin | | | | mass ratio | solvent, | siloxane | tration |
| | diameter) | (Mw) | Solvent | Acid | | [% by mass] | % by mass] | resin | [% by mass] |
| Example 13 | Polymer | Siloxane | Water/ | Acetic acid | | 7/93 | — | 2850 | 3.7 |
| | particles-1 | resin-1 | IPA | (pKa: 4.76) | | | | | |
| | (100 nm) | (Mw: 2850) | | | | | | | |
| Example 14 | Polymer | Siloxane | Water/ | Acetic acid | | 7/93 | — | 2850 | 3.7 |
| | particles-10 | resin-1 | IPA | (pKa: 4.76) | | | | | |
| | (100 nm) | (Mw: 2850) | | | | | | | |
| Example 15 | Polymer | Siloxane | Water/ | Acetic acid | | 7/93 | — | 2850 | 3.7 |
| | particles-10 | resin-1 | IPA | (pKa: 4.76) | | | | | |
| | (100 nm) | (Mw: 2850) | | | | | | | |
| Example 16 | Polymer | Siloxane | Water/ | Acetic acid | | 7/93 | — | 2850 | 3.7 |
| | particles-10 | resin-1 | IPA | (pKa: 4.76) | | | | | |
| | (100 nm) | (Mw: 2850) | | | | | | | |
| Example 17 | Polymer | Siloxane | Water/ | Acetic acid | | 7/93 | — | 2850 | 1.5 |
| | particles-10 | resin-1 | IPA | (pKa: 4.76) | | | | | |
| | (100 nm) | (Mw: 2850) | | | | | | | |
| Example 18 | Polymer | Siloxane | Water/ | Acetic acid | | 7/93 | — | 2850 | 10 |
| | particles-10 | resin-1 | IPA | (pKa: 4.76) | | | | | |
| | (100 nm) | (Mw: 2850) | | | | | | | |
| Example 19 | Polymer | Siloxane | Water/ | Acetic acid | | 7/93 | — | 2850 | 18 |
| | particles-10 | resin-1 | IPA | (pKa: 4.76) | | | | | |
| | (100 nm) | (Mw: 2850) | | | | | | | |
| Example 20 | Polymer | Siloxane | Water/ | Acetic acid | | 7/93 | — | 2850 | 21 |
| | particles-10 | resin-1 | IPA | (pKa: 4.76) | | | | | |
| | (100 nm) | (Mw: 2850) | | | | | | | |
| Example 21 | Polymer | Siloxane | Water/ | Acetic acid | | 30/70 | — | 2850 | 3.7 |
| | particles-1 | resin-1 | IPA | (pKa: 4.76) | | | | | |
| | (100 nm) | (Mw: 2850) | | | | | | | |
| Example 22 | Polymer | Siloxane | Water/ | Acetic acid | | 50/50 | — | 2850 | 3.7 |
| | particles-1 | resin-1 | IPA | (pKa: 4.76) | | | | | |
| | (100 nm) | (Mw: 2850) | | | | | | | |
| Example 23 | Polymer | Siloxane | Water/ | Acetic acid | | 80/20 | — | 2850 | 3.7 |
| | particles-1 | resin-1 | IPA | (pKa: 4.76) | | | | | |
| | (lOOnm) | (Mw: 2850) | | | | | | | |
| Example 24 | Polymer | Siloxane | Water/ | Acetic acid | | 7/93 | — | 2850 | 3.7 |
| | particles-9 | resin-1 | IPA | (pKa: 4.76) | | | | | |
| | (100 nm) | (Mw: 2850) | | | | | | | |
| Example 25 | Polymer | Siloxane | Water/ | Acetic acid | Nitric acid | 7/93 | — | 2850 | 3.7 |
| | particles-1 | resin-1 | IPA | (pKa: 4.76) | (pKa: −1.4) | | | | |
| | (100 nm) | (Mw: 2850) | | | | | | | |

| | | | | | | | | |
|---|---|---|---|---|---|---|---|---|
| Example 26 | Polymer | Siloxane | Water/ | Acetic acid | 7/93 | 2.0 | 2850 | 3.7 |
| | particles-1 | resin-1 | IPA/PGME | (pKa: 4.76) | | | | |
| | (100 nm) | (Mw: 2850) | | | | | | |
| Example 27 | Polymer | Siloxane | Water/ | Acetic acid | 7/93 | 9.5 | 2850 | 3.7 |
| | particles-1 | resin-1 | IPA/PGME | (pKa: 4.76) | | | | |
| | (100 nm) | (Mw: 2850) | | | | | | |
| Example 28 | Polymer | Siloxane | Water/ | Acetic acid | 7/93 | 19.0 | 2850 | 3.7 |
| | particles-1 | resin-1 | IPA/PGME | (pKa: 4.76) | | | | |
| | (100 nm) | (Mw: 2850) | | | | | | |
| Example 29 | Polymer | Siloxane | Water/ | Acetic acid | 7/93 | — | 2850 | 3.7 |
| | particles-1 | resin-1 | IPA | (pKa: 4.76) | | | | |
| | (100 nm) | (Mw: 2850) | | | | | | |

| | | | | Evaluation | | | | | |
|---|---|---|---|---|---|---|---|---|---|
| | | Amount of | | | | | | | Antifouling |
| | Polymer | trialkoxysi- | | | | | | | property |
| | particles/ | lane unit in | | In-plane | | Average | | | (tape |
| | siloxane | siloxane | | film | Anti- | transmit- | AR | Scratch | adhesive |
| | resin | resin | | thickness | reflection | tance | perfor- | resis- | deposit |
| | (SiO₂-equivalent) | [% by mass] | pH | unevenness | property | [%] | mance | tance | property) |
| Example 13 | 0.2 | 100 | 5 | A | 4 | 94.3 | 2.6 | 4H | 5 |
| Example 14 | 0.9 | 100 | 5 | A | 4 | 94.4 | 2.7 | 4H | 5 |
| Example 15 | 1.2 | 100 | 5 | A | 3 | 94.1 | 2.4 | 4H | 5 |
| Example 16 | 0.06 | 100 | 5 | A | 3 | 93.8 | 2.1 | 4H | 5 |
| Example 17 | 0.4 | 100 | 5 | A | 5 | 94.6 | 2.9 | 4H | 5 |
| Example 18 | 0.4 | 100 | 5 | A | 5 | 94.6 | 2.9 | 4H | 5 |
| Example 19 | 0.4 | 100 | 5 | A | 5 | 94.6 | 2.9 | 4H | 5 |
| Example 20 | 0.4 | 100 | 5 | B | 4 | 94.4 | 2.7 | 4H | 5 |
| Example 21 | 0.4 | 100 | 5 | B | 4 | 94.5 | 2.8 | 4H | 5 |
| Example 22 | 0.4 | 100 | 5 | B | 4 | 94.4 | 2.7 | 4H | 5 |
| Example 23 | 0.4 | 100 | 5 | B | 3 | 94.1 | 2.4 | 4H | 5 |
| Example 24 | 0.4 | 100 | 5 | A | 5 | 94.6 | 2.9 | 3H | 3 |
| Example 25 | 0.4 | 100 | 2 | S | 5 | 94.7 | 3.0 | 4H | 5 |
| Example 26 | 0.4 | 100 | 5 | S | 5 | 94.7 | 3.0 | 4H | 5 |
| Example 27 | 0.4 | 100 | 5 | S | 5 | 94.7 | 3.0 | 4H | 5 |
| Example 28 | 0.4 | 100 | 5 | A | 5 | 94.6 | 2.9 | 4H | 5 |
| Example 29 | 0.4 | 100 | 5 | S | 5 | 94.6 | 3.1 | 4H | 5 |

TABLE 6

| | | | | | | Weight- | | Polymer |
|---|---|---|---|---|---|---|---|---|
| | | | | | Water/ | average | Solid | particles/ |
| | Polymer | | | | organic | molecular | content | siloxane |
| | particles | Siloxane | | | solvent | weight of | concen- | resin |
| | (particle | resin | | | mass ratio | siloxane | tration | (SiO₂- |
| | diameter) | (Mw) | Solvent | Acid | [% by mass] | resin | [% by mass] | equivalent) |
| Comparative | Polymer | Siloxane | Water/ | Acetic acid | 7/93 | 580 | 3.7 | 0.4 |
| Example 1 | particles-1 | resin-8 | IPA | (pKa: 4.76) | | | | |
| | (100 nm) | (Mw: 580) | | | | | | |
| Comparative | Polymer | Siloxane | Water/ | Acetic acid | 7/93 | 6800 | 3.7 | 0.4 |
| Example 2 | particles-1 | resin-9 | IPA | (pKa: 4.76) | | | | |
| | (100 nm) | (Mw: 6800) | | | | | | |
| Comparative | Polymer | Siloxane | Water/ | Acetic acid | 7/93 | 400 | 3.7 | 0.4 |
| Example 3 | particles-1 | resin-10 | IPA | (pKa: 4.76) | | | | |
| | (100 nm) | (Mw: 400) | | | | | | |
| Comparative | Polymer | Siloxane | Water/ | Acetic acid | 7/93 | 310 | 3.7 | 0.4 |
| Example 4 | particles-1 | resin-11 | IPA | (pKa: 4.76) | | | | |
| | (100 nm) | (Mw: 310) | | | | | | |
| Comparative | Polymer | Siloxane | Water/ | Acetic acid | 7/93 | 1250 | 3.7 | 0.4 |
| Example 5 | particles-1 | resin-12 | IPA | (pKa: 4.76) | | | | |
| | (100 nm) | (Mw: 1250) | | | | | | |
| Comparative | Polymer | Siloxane | Water/ | Acetic acid | 7/93 | 2300 | 3.7 | 0.4 |
| Example 6 | particles-1 | resin-13 | IPA | (pKa: 4.76) | | | | |
| | (100 nm) | (Mw: 2300) | | | | | | |
| Comparative | Polymer | Siloxane | Water/ | Acetic acid | 7/93 | 1900 | 3.7 | 0.4 |
| Example 7 | particles-7 | resin-1 | IPA | (pKa: 4.76) | | | | |
| | (2 nm) | (Mw: 2850) | | | | | | |
| Comparative | Polymer | Siloxane | Water/ | Acetic acid | 7/93 | 2850 | 3.7 | 0.4 |
| Example 8 | particles-8 | resin-1 | IPA | (pKa: 4.76) | | | | |
| | (230 nm) | (Mw: 2850) | | | | | | |

| | | | Evaluation | | | | | |
|---|---|---|---|---|---|---|---|---|
| | Amount of | | | | | | | Antifouling |
| | trialkoxysi- | | | | | | | property |
| | lane unit in | | In-plane | | | Average | | (tape |
| | siloxane | | film | AR | Anti- | transmit- | Scratch | adhesive |
| | resin | | thickness | perfor- | reflection | tance | resis- | deposit |
| | [% by mass] | pH | unevenness | mance | property | [%] | tance | property) |
| Comparative | 100 | 5 | A | 2.9 | 5 | 94.6 | F | 5 |
| Example 1 | | | | | | | | |
| Comparative | 100 | 5 | A | 2.9 | 5 | 94.6 | H | 2 |
| Example 2 | | | | | | | | |
| Comparative | 100 | 5 | A | 2.9 | 5 | 94.6 | F | 2 |
| Example 3 | | | | | | | | |
| Comparative | 100 | 5 | A | 2.9 | 5 | 94.6 | F | 5 |
| Example 4 | | | | | | | | |
| Comparative | 100 | 5 | A | 2.9 | 5 | 94.6 | H | 2 |
| Example 5 | | | | | | | | |
| Comparative | 90 | 5 | A | 2.9 | 5 | 94.6 | 3H | 1 |
| Example 6 | | | | | | | | |
| Comparative | 100 | 5 | A | 1.6 | 1 | 93.3 | 4H | 5 |
| Example 7 | | | | | | | | |
| Comparative | 100 | 5 | A | 2.0 | 2 | 93.7 | F | 2 |
| Example 8 | | | | | | | | |

The details of abbreviations shown in Table 1, Table 2, Table 3, Table 4, Table 5, and Table 6 are as described below.

Polymer particles 1: Nonionic polymer particles, number-average primary particle diameter: 100 nm, solid content: 30% by mass, a nonionic reactive emulsifier having an ethylene oxide chain (trade name: LATEMUL PD-450, manufactured by KAO Corporation) was used as an emulsifier.

Polymer particles 2: Nonionic polymer particles, number-average primary particle diameter: 35 nm, solid content: 30% by mass, a nonionic reactive emulsifier having an ethylene oxide chain (trade name: LATEMUL PD-450, manufactured by KAO Corporation) was used as an emulsifier.

Polymer particles 3: Nonionic polymer particles, number-average primary particle diameter: 55 nm, solid content: 30% by mass, a nonionic reactive emulsifier having an ethylene oxide chain (trade name: LATEMUL PD-450, manufactured by KAO Corporation) was used as an emulsifier.

Polymer particles 4: Nonionic polymer particles, number-average primary particle diameter: 63 nm, solid content: 30% by mass, a nonionic reactive emulsifier having an ethylene oxide chain (trade name: LATEMUL PD-450, manufactured by KAO Corporation) was used as an emulsifier.

Polymer particles 5: Nonionic polymer particles, number-average primary particle diameter: 130 nm, solid content: 30% by mass, a nonionic reactive emulsifier having an ethylene oxide chain (trade name: LATEMUL PD-450, manufactured by KAO Corporation) was used as an emulsifier.

Polymer particles 6: Nonionic polymer particles, number-average primary particle diameter: 180 nm, solid content: 30% by mass, a nonionic reactive emulsifier having an ethylene oxide chain (trade name: LATEMUL PD-450, manufactured by KAO Corporation) was used as an emulsifier.

Polymer particles 7: Nonionic polymer particles, number-average primary particle diameter: 2 nm, solid content: 30% by mass, synthesized using a method described in Example 2 of JP4512250B.

Polymer particles 8: Nonionic polymer particles, number-average primary particle diameter: 230 nm, solid content: 30% by mass, a nonionic reactive emulsifier having an ethylene oxide chain (trade name: LATEMUL PD-450, manufactured by KAO Corporation) was used as an emulsifier.

Polymer particles 9: Anionic polymer particles, number-average primary particle diameter: 100 nm, solid content: 30% by mass, an anionic reactive emulsifier having an ethylene oxide chain (trade name: ADEKA REASOAP SR-1025, manufactured by ADEKA Corporation) was used as an emulsifier.

Siloxane resin-1: The siloxane resin obtained in Synthesis Example 2-1, Mw=2,850, the content of the specific unit (R¹: a methyl group, R²: H and/or an ethyl group): 100% by mass

Siloxane resin-2: The siloxane resin obtained in Synthesis Example 2-2, Mw=1,980, the content of the specific unit (R¹: a methyl group, R²: H and/or an ethyl group): 100% by mass

Siloxane resin-3: The siloxane resin obtained in Synthesis Example 2-3, Mw=5,900, the content of the specific unit (R¹: a methyl group, R²: H and/or an ethyl group): 100% by mass

Siloxane resin-4: The siloxane resin obtained in Synthesis Example 2-4, Mw=3,350, the content of the specific unit (R¹: a methyl group, R²: H and/or an ethyl group): 100% by mass

Siloxane resin-5: The siloxane resin obtained in Synthesis Example 2-5, Mw=1,450, the content of the specific unit (R¹: a methyl group, R²: H and/or an ethyl group): 100% by mass

Siloxane resin-6: The siloxane resin obtained in Synthesis Example 2-6, Mw=770, the content of the specific unit (R¹: a methyl group, R²: H and/or an ethyl group): 100% by mass

Siloxane resin-7: The siloxane resin obtained in Synthesis Example 2-7, Mw=5,500, the content of the specific unit (R¹: a methyl group, R²: H and/or an ethyl group): 100% by mass

Siloxane resin-8: The siloxane resin (resin for comparison) obtained in Synthesis Example 2-8, Mw=580, the content of the specific unit (R¹: a methyl group, R²: H and/or an ethyl group): 100% by mass

Siloxane resin-9: The siloxane resin (resin for comparison) obtained in Synthesis Example 2-9, Mw=6,800, the content of the specific unit (R¹: a methyl group, R²: H and/or an ethyl group): 100% by mass

Siloxane resin-10: The siloxane resin (resin for comparison) obtained in Synthesis Example 2-10, Mw=400

Siloxane resin-11: The siloxane resin (resin for comparison) obtained in Synthesis Example 2-11, Mw=310, the content of the specific unit (R¹: a methyl group, R²: H and/or an ethyl group): 100% by mass

Siloxane resin-12: The siloxane resin (resin for comparison) obtained in Synthesis Example 2-12, Mw=1,250, the content of a unit in which R¹ in the specific unit was changed to a phenyl group and R² was a methyl group was 100% by mass

Siloxane resin-13: The siloxane resin (resin for comparison) obtained in Synthesis Example 2-13, Mw=2,300, the content of the specific unit (R¹: a methyl group, R²: H and/or an ethyl group): 90% by mass

Acetic acid aqueous solution: Acetic acid (manufactured by Wako Pure Chemical Industries, Ltd., pKa: 4.76) was diluted with deionized water, thereby preparing a 20% by mass aqueous solution of acetic acid.

Nitric acid aqueous solution: Nitric acid (manufactured by Wako Pure Chemical Industries, Ltd., d.1.38, pKa: −1.4) was diluted with deionized water, thereby preparing a 40% by mass aqueous solution of nitric acid.

Water: Deionized water

IPA: 2-Propanol, manufactured by Tokuyama Corporation

PGME: 1-Methoxy-2-propanol, manufactured by Nippon Nyukazai Co., Ltd.

<Evaluation>

The following evaluations were carried out using the laminates having the antireflection film produced using the coating fluids obtained in the above-described examples and comparative examples. The evaluation results are shown in Table 4, Table 5, and Table 6.

(1) Antireflection (AR) Property

The reflectivity (%) of the laminate having the antireflection film formed on the glass base material for light rays having wavelengths of 380 nm to 1,100 nm was measured using an UV-Vis-NIR spectrometer (product No.: UV3100PC, manufactured by Shimadzu Corporation) and an integrating sphere. The reflectivity was measured after black tape was attached to a surface of the glass base material which became a rear surface (a surface of the glass base material on a side on which the sample film was not formed) in order to suppress the reflection on the rear surface of the laminate. In addition, the average reflectivity (R^{AV}, unit: %) of the laminate was computed from the reflectivity values at the respective wavelength of the measured wavelengths of 380 nm to 1,100 nm.

The reflectivity (%) of a glass base material was measured in the same manner as described above, and the average reflectivity (R^{0AV}, unit: %) of the glass base material was computed.

An antireflection property (ΔR) was computed from the average reflectivity values R^{AV} and W^{AV} according to Expression (a).

A larger numerical value of ΔR indicates a more favorable antireflection (AR) property.

ΔR=R^{0AV}−R^{AV} Expression (a)

The computed antireflection property (AR) was ranked according to evaluation points described below. Ranks 3 to 5 are the permissible range of the antireflection property.

(Evaluation Points) (Antireflection Property (ΔR))

5 2.8<ΔR≤3.1

4 2.4<ΔR≤2.8

3 2.0<ΔR2.4

2 1.6<ΔR≤2.0

1 1.2<ΔR≤11.6

(2) Average Transmittance

The transmittance (%) of the laminate having the antireflection film formed on the glass base material for light rays having wavelengths of 380 nm to 1,100 nm was measured using an UV-Vis-NIR spectrometer (product No.: UV3100PC, manufactured by Shimadzu Corporation) and an integrating sphere.

The average transmittance (T^{AV}, unit: %) of the laminate was computed from the measurement values of the transmittance at the respective wavelengths of 380 nm to 1,100 nm.

(3) Scratch Resistance (Pencil Hardness)

The pencil hardness of a film surface (a surface of an antireflection film) of the sample film was measured according to a method described in JIS K-5600-5-4 (1999) using UNI (registered trademark) manufactured by Mitsubishipencil Co., Ltd. as a pencil.

The pencil hardness is preferably high, and the permissible range of the pencil hardness is B or higher and particularly preferably 3H or higher. Meanwhile, in the present specification, for example, the expression “the pencil hardness is B or higher” indicates that the pencil hardness is B or harder than B (for example, HB, F, H, or the like).

(4) Antifouling Property (Tape Adhesive Deposit Property)

CELLOTAPE (registered trademark) (manufactured by Nichiban Co., Ltd., width: 18 mm, length: 56 mm) was attached to the film surface of the sample film, and the tape was tightly attached to the sample film by rubbing the tape with an eraser. After one minute from the attachment of the tape, the tape was instantaneously pulled and peeled off at a right angle with respect to the surface of the sample film by grabbing an end of the tape.

After that, the region in the sample film to which the tape had been attached was divided into 100 (10 rows and 10 columns) continuous squares, and the number (x) of, out of the 100 squares, squares in which a pressure-sensitive adhesive of the tape was not peeled off and remained was measured. A smaller value of x indicates a more favorable antifouling property (tape adhesive deposit property). The permissible range of the tape adhesive deposit property is the number (x) of the squares being 9 or less and preferably 6 or less.

The number (x) of the squares measured was ranked according to evaluation points described below. Ranks 3 to 5 are the permissible range of the tape adhesive deposit property.

(Evaluation points) (Number (x) of squares in which adhesive remains)

5 0 to 3 squares

4 4 to 6 squares

3 7 to 9 squares

2 10 to 12 squares

1 13 or more squares

(5) Film thickness unevenness in plane

For the film thicknesses measured in the above-described section “the production of laminates having an antireflection film”, the standard deviation σ of the film thicknesses measured at 10 places was computed.

A smaller value of the standard deviation σ indicates a smaller film thickness unevenness.

The permissible range of the film thickness unevenness is a standard deviation σ of the film thickness being 15 nm or less, preferably 10 nm or less, and more preferably 5 nm or less.

(Evaluation level) (Standard Deviation σ)

S 0 nm≤σ≤5 nm

A 5 nm<σ≤0 nm

B 10 nm<σ≤15 nm

C 15 nm<σ

From the results of Example 1 to Example 28, it is found that the coating compositions of the examples were all excellent in terms of the antireflection property, the scratch resistance, and the antifouling property (tape adhesive deposit property) of the film to be obtained. In addition, it is found that the unevenness in the in-plane film thickness was small and favorable result was obtained.

From the results of Example 1, Comparative Example 1, and Comparative Example 4, it is found that, in a case where the coating composition includes a siloxane resin having a molecular weight of more than 6,000, the scratch resistance of the film is significantly poor.

From the results of Example 1 and Comparative Example 2, it is found that, in a case where the coating composition includes a siloxane resin having a molecular weight of less than 600, both the scratch resistance and the antifouling property (tape adhesive deposit property) of the film are poor.

From the results of Example 1, Comparative Example 3, and Comparative Example 5, it is found that, in a case where the coating composition does not include the specific unit and includes a siloxane resin having a unit having a phenyl group, both the scratch resistance and the antifouling property (tape adhesive deposit property) of the film are poor, which is still true even in a case where the molecular weight of the siloxane resin is in a range of 600 to 6,000.

From the results of Example 1 and Comparative Example 6, it is found that, in a case where the coating composition includes a siloxane resin in which the content of the specific unit is less than 95% by mass, the antifouling property (tape adhesive deposit property) is poor.

From the results of Example 1, Comparative Example 7, and Comparative Example 8, it is found that, in a case where the coating composition includes polymer particles having a number-average primary particle diameter of less than 30 nm, the antireflection property is poor, and, in a case where the coating composition includes polymer particles having a number-average primary particle diameter of more than 200 nm, an antireflection property, scratch resistance, and an antifouling property (tape adhesive deposit property) cannot be obtained.

From the results of Example 13 to Example 16, it is found that, in a case where, in the coating composition, the proportion of the mass of the specific polymer particles in the SiO₂-equivalent mass of the specific siloxane resin is 0.1 or more and 1 or less, a film that is superior in terms of the antireflection property and also excellent in terms of the scratch resistance and the antifouling property (tape adhesive deposit property) can be obtained.

From the results of Example 17 to Example 20, it is found that, in a case where the concentration of the solid contents of the coating composition is 1% by mass to 20% by mass, a film that is superior in terms of the antireflection property and also excellent in terms of the scratch resistance and the antifouling property (tape adhesive deposit property) can be obtained.

From the results of Example 20 to Example 23, it is found that, in a case where the solvent in the coating composition is made up of water and 2-propanol (organic solvent) and the content of 2-propanol is 50% by mass or more of the total mass of the solvent, a film that is superior in terms of the antireflection property and also excellent in terms of the scratch resistance and the antifouling property (tape adhesive deposit property) can be obtained.

From the results of Example 1 and Example 24, it is found that, in a case where, in the coating composition, the specific polymer particles are nonionic particles, a film that is superior in terms of both the scratch resistance and the antifouling property (tape adhesive deposit property) can be obtained.

From the results of Example 25, it is found that, in a case where the coating composition includes an acid having a pKa of 4 or less and the pH of the coating composition is 1 to 4, a film having a smaller unevenness in the in-plane film thickness can be obtained.

From the results of Example 26 to Example 28, it is found that, in a case where an organic solvent having a high boiling point is contained, the unevenness in film thickness is reduced, and the antireflection property improves.

### Example 30

The laminate having the antireflection film on the surface of the figured glass produced in Example 1, an ethylene-vinyl acetate copolymer (EVA) sheet (SC50B manufactured by Mitsui Chemicals, Inc.), a crystalline solar cell, an EVA sheet (SC50B manufactured by Mitsui Chemicals, Inc.), and a back sheet (manufactured by Fujifilm Corporation) were overlaid in this order so that the surface of the laminate on which the sample film (antireflection film) was present became the outermost layer, vacuumed at 128° C. for three minutes using a vacuum laminator (manufactured by Nisshinbo Holdings Inc., vacuum laminator), and then pressurized for two minutes, thereby being temporarily adhered together. After that, a main adhesion treatment was carried out in a dry oven at 150° C. for 30 minutes. At that time, some of EVA overflowed onto the sample film (antireflection film), but it was possible to easily peel the laminate off

A crystalline solar cell module was produced as described above. The produced solar cell module was operated outdoors for 100 hours to generate electric power and consequently exhibited a favorable power generation performance as a solar cell.

### Examples 31 to 58

Solar cell modules were produced in the same manner as in Example 30 except for the fact that the laminate having the antireflection film produced in Example 1 and used in Example 30 was changed to the laminates having the antireflection film produced in Example 2 to Example 29.

All of the solar cell modules exhibited favorable power generation performance as solar cells after being operated for 100 hours outdoors to generate electric power.

The coating composition according to the embodiment of the present disclosure is preferred in technical fields that demand a high transmittance of incident light and are exposed to environments that easily receive external forces and is preferably used in, for example, members on the light incident side (front glass, lenses, and the like) of optical lenses, optical filters, surveillance cameras, indicators, solar cell modules, and the like, protective films and antireflection films that are provided to members of lighting equipment on the light irradiation side (diffusion glass and the like), flattening films for thin film transistors (TFT) of a variety of displays, and the like.

The disclosures of JP2017-019965 filed on Feb. 6, 2017, JP2017-094246 filed on May 10, 2017, and JP2017-244484 filed on Dec. 20, 2017 are incorporated into the present specification by reference in their entirety.

All of documents, patent applications, and technical standards described in the present specification are incorporated into the present specification by reference as if the respective documents, patent applications, and technical standards are specifically and respectively described to be incorporated by reference.

What is claimed is:

1. A coating composition comprising:
polymer particles having a number-average primary particle diameter of 30 nm to 200 nm;
a siloxane resin which has a weight-average molecular weight of 600 to 6,000, is a siloxane resin including at least one unit selected from units (1), (2), and (3) described below, and has a total mass of the units (1), (2), and (3) being 95% by mass or more of a total mass of the siloxane resin; and
a solvent,
unit (1): R¹—Si(OR²)₂O_{1/2} unit,
unit (2): R¹—Si(OR²)O_{2/2} unit, and
unit (3): R¹—Si—O_{3/2} unit,
in the units (1), (2), and (3), R¹'s each independently represent an alkyl group having 1 to 8 carbon atoms or an alkyl fluoride group having 1 to 8 carbon atoms, R²'s each independently represent a hydrogen atom or an alkyl group having 1 to 8 carbon atoms, and, in a case where both the units (1) and (2) are included, the alkyl groups having 1 to 8 carbon atoms represented by R¹'s or R²'s may be identical to or different from each other.

2. The coating composition according to claim 1,
wherein a proportion of a mass of the polymer particles in a SiO₂-equivalent mass of the siloxane resin is 0.1 or more and 1 or less.

3. The coating composition according to claim 1,
wherein a concentration of solid contents is 1% by mass to 20% by mass.

4. The coating composition according to claim 1,
wherein the solvent is made up of water and an organic solvent, and a content of the organic solvent is 50% by mass or more of a total mass of the solvent.

5. The coating composition according to claim 4,
wherein the organic solvent includes an organic solvent having a high boiling point, and a content of the organic solvent having a high boiling point is 1% by mass or more and 20% by mass or less of the total mass of the solvent.

6. The coating composition according to claim 1,
wherein the polymer particles are nonionic polymer particles.

7. The coating composition according to claim 1,
wherein a pH of the coating composition is 1 to 4.

8. The coating composition according to claim 1,
wherein the coating composition further includes an acid, and a pKa of the acid is 4 or less.

9. The coating composition according to claim 8,
wherein the acid is an inorganic acid.

10. An antireflection film which is a cured substance of the coating composition according to claim 1.

11. The antireflection film according to claim 10,
wherein an average film thickness is 80 nm to 200 nm.

12. A laminate comprising:
a base material; and
the antireflection film according to claim 10.

13. The laminate according to claim 12,
wherein the base material is a glass base material.

14. A solar cell module comprising:
the laminate according to claim 12.

15. A laminate comprising:
a base material; and
an antireflection film formed on the base material,
wherein the antireflection film has holes having a hole diameter of 30 nm to 200 nm in a matrix containing silica as a main component, the number of holes that are opened on an outermost surface of the antireflection film and have a diameter of 20 nm or more is 13 holes/10⁶ nm² or less, an average transmittance (T^{AV}) at a wavelength of 380 to 1,100 nm is 94.0% or more, and a pencil hardness measured using a method described in JIS K-5600-5-4 (1999) is 3H or higher.

16. The laminate according to claim 15,
wherein an average film thickness of the antireflection film is 80 nm to 200 nm, and a standard deviation σ of film thicknesses is 5 nm or less.

17. The laminate according to claim 15,
wherein the base material is a glass base material.

18. A solar cell module comprising:
the laminate according to claim 15.

19. A method for manufacturing an antireflection film comprising:
a step of forming a coating film by applying the coating composition according to claim 1 onto a base material;
a step of drying the coating film formed by application; and
a step of firing the dried coating film.
